(19) United States
(12) Patent Application Publication
(10) Pub. No.: US 2023/0378114 A1
(43) Pub. Date: Nov. 23, 2023

(54) DISPLAY DEVICE

(71) Applicant: SONY SEMICONDUCTOR SOLUTIONS CORPORATION, KANAGAWA (JP)

(72) Inventors: YUICHI MIYAMORI, KANAGAWA (JP); KENJI MORIYAMA, KANAGAWA (JP)

(21) Appl. No.: 18/248,497

(22) PCT Filed: Oct. 19, 2021
(86) PCT No.: PCT/JP2021/038635

§ 371 Date: Apr. 10, 2023

(30) Foreign Application Priority Data
Oct. 22, 2020 (JP) 2020-177495

(51) Int. Cl. H01L 23/00; H01L 27/15; H01L 25/18

(52) U.S. Cl. CPC H01L 24/13; H01L 27/156; H01L 25/18; H01L 24/16; H01L 24/14; H01L 2224/13012; H01L 2224/13155; H01L 2224/13139; H01L 2224/13144; H01L 2224/13147; H01L 2224/13111; H01L 2924/0132; H01L 2224/14131; H01L 2224/16145; H01L 2924/12041

(57) ABSTRACT

To provide a display device that can suppress scattered light generated when light leaking downward from a semiconductor light-emitting element of one subpixel is scattered at a joint, from leaking to an adjacent subpixel. The display device includes a display panel including a plurality of semiconductor light-emitting elements each including a light-emitting layer, a drive substrate having a drive circuit and facing the display panel, and a plurality of joints each electrically connecting each of a plurality of the semiconductor light-emitting elements to the drive substrate, in which, in a case where a direction in which the display panel and the drive substrate face each other is a line-of-sight direction, a position of a center of a light-emitting region of the semiconductor light-emitting element and a position of a center of the joint to be joined to the semiconductor light-emitting element are shifted from each other.

### TECHNICAL FIELD

The present disclosure relates to a display device, and particularly to a display device having a plurality of semiconductor light-emitting elements.

### BACKGROUND ART

As a display device having a plurality of semiconductor light-emitting elements, there has been proposed a device including a display panel having a plurality of semiconductor light-emitting elements forming subpixels and a drive substrate having a drive circuit, and having a bump joint as a joint that electrically connects each semiconductor light-emitting element and the drive substrate. Conventionally, as disclosed in Patent Document 1, in a case where a direction from the display panel to the drive substrate is a downward direction, the bump joint is disposed immediately below the semiconductor light-emitting element.

### CITATION LIST

### Patent Document

Patent Document 1: Japanese Patent Application Laid-Open No. 2018-182282

### SUMMARY OF THE INVENTION

### Problems to be Solved by the Invention

In the technique of Patent Document 1, scattered light is generated when light leaking downward from the semiconductor light-emitting element present in one subpixel is scattered at the bump joint. The technique of Patent Document 1 has room for improvement in avoiding scattered light from leaking toward a subpixel adjacent to the subpixel.

The present disclosure has been made in view of the above-described points, and an object of the present disclosure is to provide a display device that can suppress scattered light, which is generated when light leaking downward from a semiconductor light-emitting element of one subpixel is scattered at a joint, from leaking to an adjacent subpixel.

### Solution to Problems

The present disclosure is, for example, a display device including:
a display panel including a plurality of semiconductor light-emitting elements, each of the plurality of semiconductor light-emitting elements including a light-emitting layer;
a drive substrate having a drive circuit and facing the display panel; and
a plurality of joints, each of the plurality of joints electrically connecting each of a plurality of the semiconductor light-emitting elements to the drive substrate, in which
in a case where a direction in which the display panel and the drive substrate face each other is a line-of-sight direction, the semiconductor light-emitting element has a light-emitting region whose position at a center is shifted from a position of a center of the joint to be joined to the semiconductor light-emitting element.

### BRIEF DESCRIPTION OF DRAWINGS

FIG. 1 is a schematic cross-sectional view of an example of a display device according to a first embodiment.

FIG. 2 is a schematic plan view of the example of the display device according to the first embodiment.

FIG. 3 is a schematic cross-sectional view of a modified example of the display device according to the first embodiment.

FIG. 4 is a schematic cross-sectional view of a modified example of the display device according to the first embodiment.

FIG. 5 is a schematic plan view of a modified example of the display device according to the first embodiment.

FIG. 6 is a schematic plan view of a modified example of the display device according to the first embodiment.

FIG. 7 is a schematic plan view of a modified example of the display device according to the first embodiment.

FIG. 8 is a schematic plan view of a modified example of the display device according to the first embodiment.

FIG. 9 is a schematic plan view of a modified example of the display device according to the first embodiment.

FIG. 10 is a schematic plan view of a modified example of the display device according to the first embodiment.

FIG. 11 is a schematic plan view of a modified example of the display device according to the first embodiment.

FIGS. 12A to 12E are schematic cross-sectional views for explaining an example of a manufacturing method of the display device according to the first embodiment.

FIGS. 13A to 13C are schematic cross-sectional views for explaining the example of the manufacturing method of the display device according to the first embodiment.

FIGS. 14A to 14D are schematic cross-sectional views for explaining the example of the manufacturing method of the display device according to the first embodiment.

FIG. 15 is a schematic cross-sectional view of an example of a display device according to a second embodiment.

FIG. 16 is a schematic plan view of the example of the display device according to the second embodiment.

FIG. 17 is a schematic cross-sectional view of another example of a display device according to the second embodiment.

FIG. 18 is a schematic plan view of a modified example of the display device according to the second embodiment.

FIG. 19 is a schematic plan view of a modified example of the display device according to the second embodiment.

FIG. 20 is a schematic plan view of a modified example of the display device according to the second embodiment.

FIG. 21 is a schematic plan view of a modified example of the display device according to the second embodiment.

FIG. 22 is a schematic plan view of a modified example of the display device according to the second embodiment.

FIG. 23 is a schematic plan view of a modified example of the display device according to the second embodiment.

FIGS. 24A to 24D are schematic cross-sectional views for explaining an example of a manufacturing method of the display device according to the second embodiment.

FIG. 25 is a schematic cross-sectional view of an example of a display device according to a third embodiment.

FIGS. 26A to 26D are schematic cross-sectional views for explaining an example of a manufacturing method of the display device according to the third embodiment.

FIGS. 27A to 27E are schematic cross-sectional views for explaining the example of the manufacturing method of the display device according to the third embodiment.

### MODE FOR CARRYING OUT THE INVENTION

Hereinafter, an example and the like according to the present disclosure are described with reference to the drawings. Note that the description is given in the following order. In the present description and the drawings, configurations having substantially the same functional configurations are denoted by the same reference numerals, and redundant description is omitted.

Note that the description is given in the following order.
1. First Embodiment
2. Second Embodiment
3. Third Embodiment

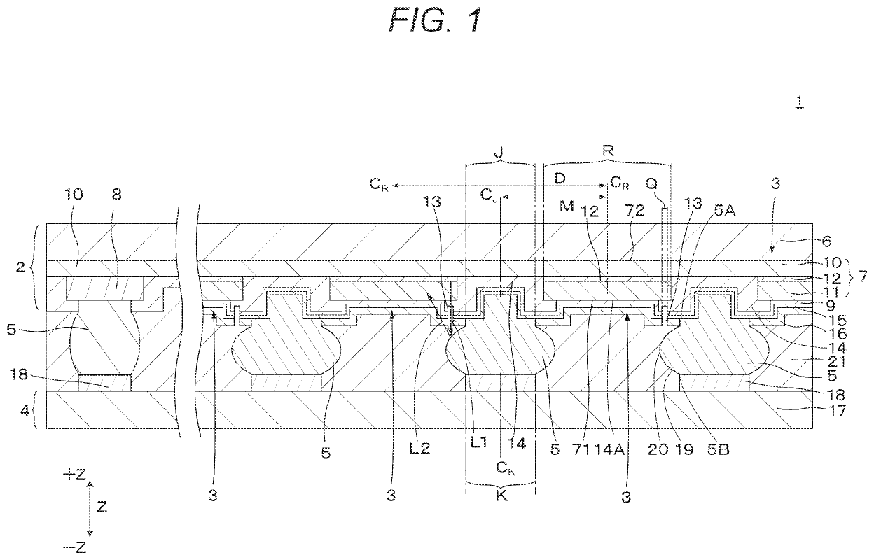

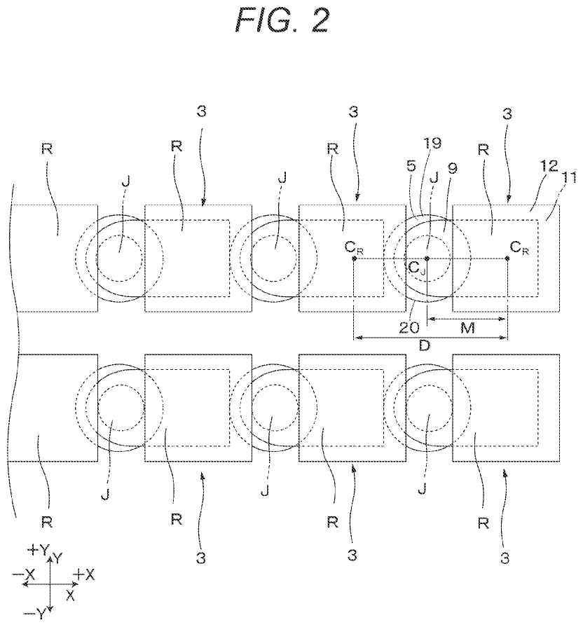

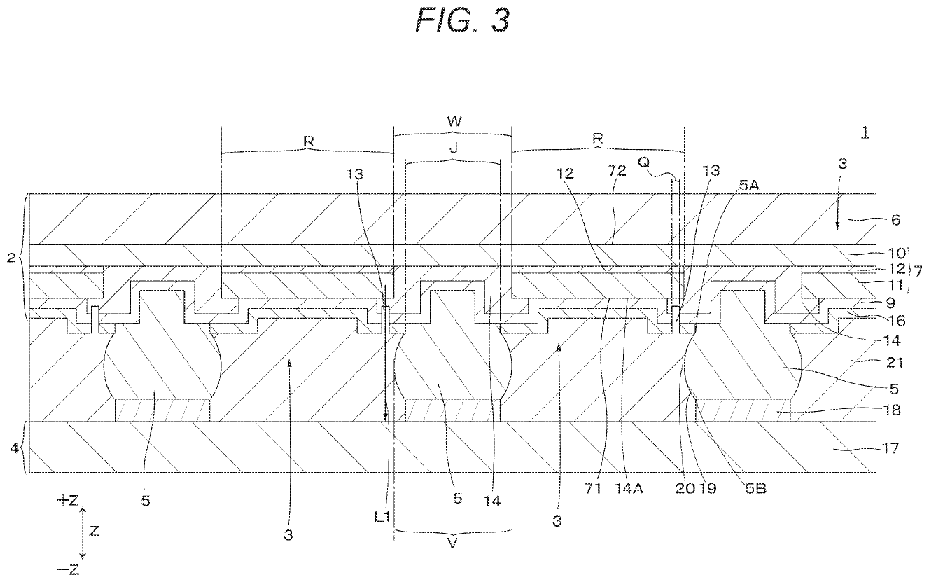

The following description is a preferred specific example of the present disclosure, and the content of the present disclosure is not limited to these embodiments and the like. Furthermore, in the following description, directions such as front and back, left and right, up and down, and the like are indicated in consideration of convenience of description, but the content of the present disclosure is not limited to these directions. In the examples in FIGS. 1, 2, and the like, it is assumed that the Z-axis direction is the up-down direction (the upper side is +Z direction and the lower side is −Z direction), the X-axis direction is the front-rear direction (the front side is +X direction and the rear side is −X direction), and the Y-axis direction is the left-right direction (the right side is +Y direction and the left side is −Y direction), and the description is made on the basis of this. This is applied similarly in FIGS. 3 to 27. The relative magnitude ratios of the sizes and thicknesses of the layers shown in each of the drawings such as FIG. 1 are described for convenience, and do not limit actual magnitude ratios. This is applied similarly in each of the drawings from FIGS. 3 to 27 regarding the definition and the magnitude ratio regarding these directions.

### 1. First Embodiment

### 1-1. Configuration of Display Device

As shown in FIG. 1, a display device 1 according to the first embodiment includes a display panel 2 having a plurality of semiconductor light-emitting elements 3, a drive substrate 4 having a drive circuit, and a joint that electrically connects the semiconductor light-emitting elements 3 and the drive substrate 4. FIG. 1 is a cross-sectional view showing an example of a configuration of the display device 1 according to the first embodiment. Note that, in the display device 1 according to the first embodiment, the joint is a bump joint 5 as described later.

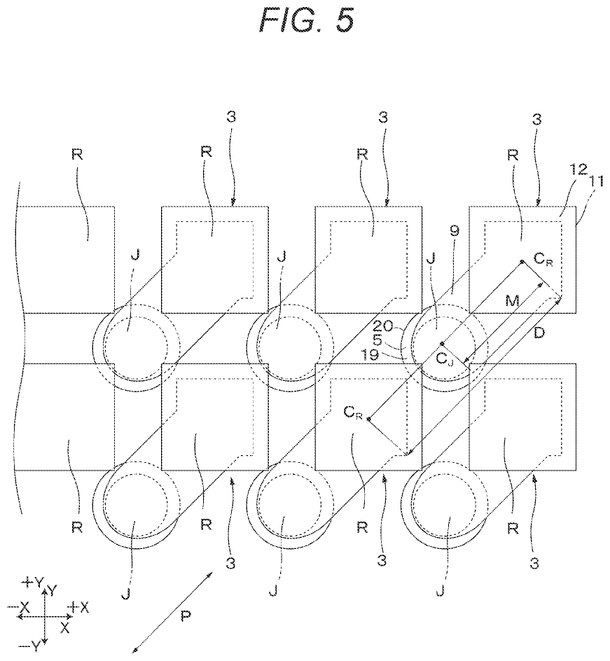

Furthermore, in FIG. 1 and the like, for convenience of description, the Z axis is defined parallel to the direction in which the display panel 2 and the drive substrate 4 face each other (hereinafter, simply referred to as a facing direction), and the in-plane direction of the two-dimensional plane defined by the X axis and the Y axis is aligned with the in-plane direction of the main surface of the display panel 2. In addition, in the examples in FIGS. 1 and 2 and the like, the semiconductor light-emitting elements 3 are arranged in a matrix, and the X axis and the Y axis are defined along the alignment direction of the semiconductor light-emitting elements 3. FIG. 2 is a schematic plan view showing the alignment of the semiconductor light-emitting elements 3 of the display device 1 of the example in FIG. 1. In FIG. 2, for convenience of description, arrangement of a light-emitting layer 12, the second compound semiconductor layer 11, a second electrode 9, and the joint (bump joint 5) in the −Z direction from the light-emitting layer 12 is shown, and description of other layers and the like is omitted. This applies similarly to schematic plan views showing the alignment of the semiconductor light-emitting elements 3 of the display device 1 described in FIGS. 5 to 11, 16, and 18 to 23. In addition, in FIG. 2, the description of a seed layer 15 is also omitted. This is applied similarly in FIGS. 3 to 27. Note that a case where the direction in which the display panel 2 and the drive substrate 4 face each other is the line-of-sight direction indicates a case where the direction along the Z axis is the line-of-sight direction in the example in FIG. 1. Furthermore, in the display device 1, a direction from the drive substrate 4 toward the display panel 2 (+Z direction) along the normal direction (Z axis) of a unit region R as described later is defined as an upward direction, and a direction that extends from the display panel 2 toward the drive substrate 4 is defined as a downward direction (−Z direction).

### (Display Panel)

The display panel 2 includes the plurality of semiconductor light-emitting elements 3. The display panel 2 has an image display region defined in a predetermined region thereof. In the image display region, a large number of pixels including subpixels are usually formed in a predetermined arrangement pattern. In the example in FIG. 2, a large number of pixels including three types of subpixels having different colors are formed in a matrix. For example, in the example in FIG. 2, combinations of the three types of subpixels may be arranged along the X-axis direction, and the subpixels of the same color may be arranged in a column along the Y-axis direction. One semiconductor light-emitting element 3 corresponds to one subpixel. In the example in FIGS. 1, 2, and the like, a laminated structure 7 as described later constituting the semiconductor light-emitting element 3 is formed for every subpixel, and a group of the plurality of laminated structures 7 is formed in the image display region.

### (Semiconductor Light-Emitting Element)

In the example in FIG. 1, the semiconductor light-emitting element 3 includes an element substrate 6, the compound semiconductor laminated structure (hereinafter, simply referred to as the “laminated structure”) 7, a first electrode 8, and the second electrode 9.

### (Element Substrate)

The element substrate 6 supports the laminated structure 7. The element substrate 6 has a first main surface on the laminated structure 7 side and a second main surface on the opposite side. The element substrate 6 is, for example, a GaAs substrate, a GaN substrate, a SiC substrate, an alumina substrate, a sapphire substrate, a ZnS substrate, a ZnO substrate, an AlN substrate, a LiMgO substrate, a LiGaO₂ substrate, a MgAl₂O₄ substrate, an InP substrate, a Si substrate, a Ge substrate, a GaP substrate, an AlP substrate, an InN substrate, an AlGaInN substrate, an AlGaN substrate, an AlInN substrate, a GaInN substrate, an AlGaInP substrate, an AlGaP substrate, an AlInP substrate, or a GaInP substrate. An underlayer, a buffer layer, and the like may be provided on the first main surface of the element substrate 6.

### (Laminated Structure)

The laminated structure 7 is provided on the first main surface of the element substrate 6. The laminated structure 7 has a first main surface 71 on the side opposite to the element substrate 6 side and a second main surface 72 on the element substrate 6 side.

The laminated structure 7 includes a plurality of laminated compound semiconductor layers. Specifically, the laminated structure 7 includes a first compound semiconductor layer 10, a second compound semiconductor layer 11, and a light-emitting layer 12. The light-emitting layer 12 is provided between the first compound semiconductor layer 10 and the second compound semiconductor layer 11. However, the configuration of the laminated structure 7 is not limited thereto, and a laminated structure other than that described above may be provided.

The first compound semiconductor layer 10 has a first main surface on the light-emitting layer 12 side and a second main surface on the opposite side to the light-emitting layer 12 side.

The first compound semiconductor layer 10 has a first conductivity type, and the second compound semiconductor layer 11 has a second conductivity type opposite to the first conductivity type. Specifically, the first compound semiconductor layer 10 has an n-type, and the second compound semiconductor layer 11 has a p-type.

The first compound semiconductor layer 10 and the second compound semiconductor layer 11 contain a compound semiconductor. The compound semiconductor is, for example, a GaN-based compound semiconductor (AlGaN mixed crystal, AlInGaN mixed crystal, or InGaN mixed crystal), an InN-based compound semiconductor, an InP-based compound semiconductor, an AlN-based compound semiconductor, a GaAs-based compound semiconductor, an AlGaAs-based compound semiconductor, an AlGaInP-based compound semiconductor, an AlGaInAs-based compound semiconductor, an AlAs-based compound semiconductor, a GaInAs-based compound semiconductor, a GaInAsP-based compound semiconductor, a GaP-based compound semiconductor, or a GaInP-based compound semiconductor.

The n-type impurity added to the first compound semiconductor layer 10 is, for example, silicon (Si), selenium (Se), germanium (Ge), tin (Sn), carbon (C), or titanium (Ti). The p-type impurity added to the second compound semiconductor layer 11 is zinc (Zn), magnesium (Mg), beryllium (Be), cadmium (Cd), calcium (Ca), barium (Ba), or oxygen (O).

The light-emitting layer 12 contains a compound semiconductor. As the compound semiconductor, the similar materials as those of the first compound semiconductor layer 10 and the second compound semiconductor layer 11 can be exemplified. The light-emitting layer 12 may be configured by including a single compound semiconductor layer, or may have a single quantum well structure (SQW structure) or a multiple quantum well structure (MQW structure).

### (First Electrode)

The display panel 2 is provided with the first electrode 8. In the example in FIG. 1, the first electrode 8 is disposed in a surface region (first main surface side) of the first compound semiconductor layer 10 so as to surround the group of the plurality of laminated structures 7, and is electrically connected to the first compound semiconductor layer 10. The first electrode 8 is connected to the first compound semiconductor layer 10 common to all of the plurality of laminated structures 7. The first electrode 8 functions as a common electrode in the plurality of semiconductor light-emitting elements 3.

The material of the first electrode 8 include, for example, indium oxide, indium-tin oxide (ITO, includes Sn-doped In₂O₃, crystalline ITO and amorphous ITO), indium-zinc oxide (IZO), indium-gallium oxide (IGO), indium-doped gallium-zinc oxide (IGZO, In—GaZnO₄), F-doped In₂O₃ (IFO), tin oxide (SnO₂), Sb-doped SnO₂ (ATO), F-doped SnO₂ (FTC)), zinc oxide (ZnO, including Al-doped ZnO, B-doped ZnO, Ga-doped ZnO), antimony oxide, spinel type oxide, and oxide having an YbFe₂O₄ structure. The first electrode 8 may be a transparent conductive layer including gallium oxide, titanium oxide, niobium oxide, nickel oxide, or the like as a base layer.

The first electrode 8 may contain, for example, at least one metal selected from the group consisting of palladium (Pd), platinum (Pt), nickel (Ni), aluminum (Al), titanium (Ti), gold (Au), and silver (Ag).

The first electrode 8 may have a single-layer configuration or a multilayer configuration (for example, Ti/Pt/Au).

### (Second Electrode)

The second electrode 9 is individually electrically connected to the second compound semiconductor layer 11 of each laminated structure 7. In the examples in FIGS. 1 and 2, the second electrode 9 extends in the −X direction from directly below the second compound semiconductor layer 11 toward an insulating layer 14 as described later. Because the second electrode 9 is formed in a shape extending from directly below the second compound semiconductor layer 11 as a base point to a position away from the directly below, the bump joint 5 can be easily formed at a position deviated from a center CR of the unit region R even if the seed layer 15 as described later is omitted.

Furthermore, a non-forming portion of the second electrode 9 is present in a partial region on the lower side (−Z direction side) of the laminated structure 7. This non-forming portion forms a non-forming part 13 of a laminate of the second electrode 9, the seed layer 15, and an inorganic film 16 as described later, and the second electrode 9 is separated between the adjacent semiconductor light-emitting elements 3 by the non-forming part 13.

The second electrode 9 may be formed in a shape similar to that of the seed layer 15 as described later, or may be formed in a shape different from that of the seed layer 15. The second electrode 9 and the seed layer 15 are preferably formed in the same shape from the viewpoint of reducing the number of manufacturing steps of the display device in that the step of forming the second electrode 9 and the step of forming the seed layer 15 can be integrated.

The material of the second electrode 9 include, for example, at least one metal (including an alloy) selected from the group consisting of gold (Au), silver (Ag), palladium (Pd), platinum (Pt), nickel (Ni), aluminum (Al), titanium (Ti), tungsten (W), vanadium (V), chromium (Cr), copper (Cu), zinc (Zn), tin (Sn), and indium (In).

The second electrode 9 may have a single-layer configuration or a multilayer configuration. As the multilayer configuration, Ti/Au, Ti/Al, Ti/Pt/Au, Ti/Al/Au, Ni/Au, AuGe/Ni/Au, Ni/Au/Pt, Ni/Pt, Pd/Pt, Ag/Pd, or the like can be exemplified. Note that the layer before “/” in the multilayer configuration is located closer to the light-emitting layer 12 side. This is applied similarly in the following description.

### (Insulating Layer)

The insulating layer 14 is formed between adjacent laminated structures 7 on the element substrate 6. The adjacent laminated structures 7 are separated by the insulating layer 14. The insulating layer 14 has a plurality of openings 14A, and the second compound semiconductor layers 11 of the separated laminated structures 7 are exposed from the openings 14A. As shown in the example in FIG. 1, the insulating layer 14 may cover a portion from a peripheral edge to a side surface (end surface) of a first surface of the second compound semiconductor layer 11. In the present description, the peripheral edge of the first surface refers to a region having a predetermined width from the peripheral edge of the first surface toward the inner side.

Examples of the insulating layer 14 include a layer containing a SiO_{X}-based material, a SiN_{Y}-based material, a SiO_{X}N_{Y}-based material, Ta₂O₅, ZrO₂, AlN, or Al₂O₃.

### (Arrangement and Shape of Semiconductor Light-Emitting Element)

In the display device 1 shown in the examples in FIGS. 1 and 2, the group of the plurality of semiconductor light-emitting elements 3 is formed in the display panel 2 by arranging the plurality of laminated structures 7 on the element substrate 6. Furthermore, the plurality of semiconductor light-emitting elements 3 is arranged two-dimensionally in a case where the direction in which the display panel 2 and the drive substrate 4 face each other is the line-of-sight direction. The arrangement pattern of the plurality of semiconductor light-emitting elements 3 is determined according to the pattern of the subpixel. In the example in FIG. 2, in a case where the Z-axis direction is the line-of-sight direction, the plurality of semiconductor light-emitting elements 3 is arranged in a matrix in the X-axis direction and the Y-axis direction. The shape of the semiconductor light-emitting element 3 is determined according to the pixel and the sub-pixel of the display device 1, similarly to the arrangement of the semiconductor light-emitting element 3. As the shape of the semiconductor light-emitting element 3, a circular shape, a hexagonal shape, and a rectangular shape (such as a square or a rectangle) can be exemplified. In the example in FIG. 2, in a case where the Z-axis direction is the line-of-sight direction, the shape of the semiconductor light-emitting element 3 is formed in a rectangular shape.

### (Light-Emission Color)

The plurality of semiconductor light-emitting elements 3 may have one type or two or more types of light-emission colors. For example, there may be three types of the light-emission color of the semiconductor light-emitting element 3, which are red, green, and blue. In the case of the example in FIG. 2, in the alignment of the semiconductor light-emitting elements, semiconductor light-emitting elements of red, green, and blue light-emission colors (red semiconductor light-emitting element, green semiconductor light-emitting element, and blue semiconductor light-emitting element) may be repeatedly aligned in the X-axis direction, and the semiconductor light-emitting elements of the same light-emission color may be aligned in the Y-axis direction. In the case of this example, there are three types of light-emission colors of the semiconductor light-emitting elements, the light-emission colors of the semiconductor light-emitting elements adjacent to each other in the X-axis direction are different from each other, and the light-emission colors of the semiconductor light-emitting elements adjacent to each other in the Y-axis direction are the same. Note that, because each semiconductor light-emitting element is arranged in each subpixel, in this example, one pixel may be constituted of three subpixels including three types of semiconductor light-emitting elements arranged in the X-axis direction.

### (Light-Emitting Region (Unit Region) of Each Semiconductor Light-Emitting Element)

In the display device 1, in a case where the Z-axis direction is set as the line-of-sight direction, the light-emitting region is individually specified for each semiconductor light-emitting element 3. In the present description, this specified light-emitting region is referred to as the unit region R.

The light-emitting region defined for the semiconductor light-emitting element 3 described above indicates a light-emitting region (a region recognized on the XY plane) of the light-emitting layer 12 in a case where the Z-axis direction is the line-of-sight direction.

In the examples in FIGS. 1 and 2, the entire formation region of the light-emitting layer 12 is the light-emitting region, that is, a region that the presence of the light-emitting layer 12 is recognized in a case where the Z-axis direction is set as the line-of-sight direction is the unit region R. Note that this is similarly applied to FIGS. 3 to 27, that is, in the present description, the description is continued using FIGS. 1 to 27 in which the unit region R is the light-emitting region of the light-emitting layer 12.

In the display device 1, as shown in FIG. 2 and the like, the adjacent unit regions R are separated from each other, and the plurality of unit regions R is two-dimensionally aligned. The alignment pattern of the unit regions R and the shape of each unit region are determined according to the alignment pattern and the shape of the semiconductor light-emitting element 3. In the examples in FIGS. 1 and 2, the alignment of the unit regions R is formed in a matrix shape, and the shape of the unit region R is a rectangular shape. The alignment directions of the unit regions R are the X-axis direction and the Y-axis direction.

The center of the unit region R indicates the geometric center of the unit region R, and is indicated by a reference numeral C_{R} in the examples in FIGS. 1 and 2. For example, in a case where the shape of the unit region R is substantially rectangular, the center C_{R} of the unit region R is located at or near an intersection of two diagonal lines defined in the rectangle. In a case where the shape of the unit region R is substantially a regular polygon, the center C_{R} of the unit region R is located substantially at the center of a circumscribed circle of the regular polygon. In a case where the shape of the unit region R is substantially circular, the center C_{R} of the unit region R is located substantially at the center of the circle. In a case where the shape of the unit region R is substantially elliptical, the center C_{R} of the unit region R is located substantially at or near an intersection of the major axis and the minor axis of the ellipse. These are applied similarly in FIGS. 2 to 27.

### (Seed Layer)

As shown in FIG. 1, the display panel 2 is preferably provided with the seed layer 15 for enhancing joining properties of the bump joint 5 as described later to the display panel 2 for every semiconductor light-emitting element 3. The seed layer 15 is electrically connected to both the bump joint 5 and the second electrode 9. The seed layer 15 shown in FIG. 1 is formed in a region extending from immediately below the laminated structure 7 onto the insulating layer 14. This makes it easy to arrange the bump joint 5 at a position shifted from the center C_{R} of the unit region R. Note that, for convenience of description, illustration of the seed layer 15 is omitted in FIGS. 2 to 27.

The arrangement pattern of the seed layer 15 is preferably similar to that of the second electrode 9 as described above. By forming in the similar arrangement pattern as the second electrode 9, the steps of forming the second electrode 9 and the seed layer 15 can be merged, and the manufacturing cost can be reduced as described above. Furthermore, a non-forming portion is also formed on the seed layer 15 according to the formation position of the non-forming portion of the second electrode 9.

The material of the seed layer 15 preferably has affinity with the material forming the bump joint 5 from the viewpoint of improving the joining properties between the semiconductor light-emitting element 3 and the bump joint 5. In addition, the material of the seed layer 15 is preferably a conductive metal which is hardly alloyed with the material forming the bump joint 5. As such a material, a metal such as nickel (Ni) can be exemplified. In this case, the seed layer 15 can also function as a barrier metal layer that suppresses diffusion of the material forming the bump joint 5 from one connection end 5A of the bump joint 5 to the semiconductor light-emitting element 3 side.

### (Inorganic Film)

In the display panel 2, the inorganic film 16 may be formed on the connection surface with the bump joint 5 on the first main surface side in a region except for a region facing bump joint 5. By having the inorganic film 16 formed, the second electrode 9 and the seed layer 15 can be protected. A non-forming portion is also formed on the inorganic film 16 according to the formation position of the non-forming portion of the second electrode 9.

### (Non-Forming Part 13)

In the example shown in FIG. 1, the non-forming part 13 of the laminated structure of the second electrode 9, the seed layer 15, and the inorganic film 16 is formed on the side of the element substrate 6 on which the laminated structure 7 is formed. The non-forming part 13 is formed according to the formation pattern of the second electrode. The second electrode 9, the seed layer 15, and the inorganic film 16 are separated for every semiconductor light-emitting element 3 by the non-forming part 13. In addition, a pass-through region Q as described later is formed by forming the non-forming part 13.

### (Pass-Through Region)

In the display device 1, the pass-through region Q is formed. The pass-through region Q is formed by a region where the unit region R overlaps with the non-forming part 13 of the laminate of the second electrode 9, the seed layer 15, and the inorganic film 16. As shown in FIG. 1, there is a case where light generated from the light-emitting layer 12 of the laminated structure 7 passes through the pass-through region Q formed in the non-forming part 13 and exits downward (−Z direction) from the drive substrate 4 side as leakage light L1.

### (Example of Semiconductor Light-Emitting Element)

As the semiconductor light-emitting element 3, a micro light-emitting diode (LED) or the like can be exemplified. In the micro LED, the light-emitting layer 12 of the laminated structure 7 described above is formed with a very fine dimension such as a dimension of micrometers or less. Because the semiconductor light-emitting element 3 is a micro LED, a display device with high definition and excellent contrast can be obtained.

### (Drive Substrate)

The drive substrate 4 includes a substrate 17 on which a drive circuit is formed. As the material of the substrate 17, the similar material as that of the element substrate 6 can be used. As the drive circuit, a logic circuit or the like can be exemplified. The drive circuit forms, for example, a circuit that controls driving of each semiconductor light-emitting element 3.

On the surface of the drive substrate 4, a pad part (not illustrated) is formed on the side facing the semiconductor light-emitting element 3. The pad part serves as a connection terminal for electrically connecting the semiconductor light-emitting element 3 to the drive circuit, and is individually provided with respect to the joint (bump joint 5). Each pad part is electrically connected to the corresponding semiconductor light-emitting element 3 via the bump joint 5. On the pad part of the drive substrate 4, similarly to the semiconductor light-emitting element 3, a seed layer 18 for enhancing the joining properties of the bump joint 5 to the drive substrate 4 is preferably formed. The seed layer 18 formed on the drive substrate 4 may include the material similar to that of the seed layer 15 formed on the display panel 2 side corresponding to each joint.

### (Joint)

Each semiconductor light-emitting element 3 is individually electrically connected to the drive substrate 4 via the joint. In the example of the display device 1 in FIG. 1, the joint electrically connecting each of the semiconductor light-emitting elements 3 to the drive substrate 4 is formed by the bump joint 5. The bump joint 5 is a joint between a bump 26 individually arranged on the semiconductor light-emitting element 3 of the display panel 2 and a bump 27 arranged on the drive substrate 4.

### (Type and Material of Bump)

The bumps 26 and 27 constituting the bump joint 5 are not particularly limited, and for example, pillar bumps, stud bumps, or the like can be exemplified. As the material of the bumps 26 and 27, solder, nickel, gold, silver, copper, tin, alloys thereof, or the like can be exemplified. As the material of the bumps 26 and 27, it is preferable to use a material having thermal reflow properties from the viewpoint of being able to easily form the bump joint. Examples of the material having the thermal reflow properties include solder and a material constituting the solder.

### (Position of Joint)

In a case where the direction in which the display panel 2 and the drive substrate 4 face each other (Z-axis direction) is the line-of-sight direction, a position of a center C_{R} of the unit region R, which is the center of the light-emitting region of the semiconductor light-emitting element 3, and a position of the center of the bump joint 5 to be joined to the semiconductor light-emitting element 3 are shifted from each other. Here, the center of the bump joint 5 means the center of an element joining region J as described later.

### (Element Joining Region and Substrate Joining Region)

As shown in FIG. 1, in the bump joint 5 as a joint, the element joining region J to be joined to the semiconductor light-emitting element 3 is formed at one end (an end in the +Z direction) (the side of the one connection end 5A), and a substrate joining region K to be joined to the drive substrate 4 is formed at the other end (an end in the −Z direction) (the side of an other connection end 5B). In FIG. 1, a reference numeral C_{J} indicates the center of the element joining region J, and a reference numeral C_{K} indicates the center of the substrate joining region K. The element joining region J indicates a region recognized on the XY plane in a case where the joining region between the bump joint 5 and the semiconductor light-emitting element 3 is viewed with the Z-axis direction as the line-of-sight direction. The substrate joining region K indicates a region recognized on the XY plane in a case where the joining region between the bump joint 5 and the drive substrate 4 is viewed with the Z-axis direction as the line-of-sight direction.

### (Formation Position of Element Joining Region)

In the display device 1, as described above, the position of the center C_{R} of the unit region R and the position of the center of the bump joint 5 are shifted from each other. That is, in a case where the direction in which the display panel 2 and the drive substrate 4 face each other (Z-axis direction) is the line-of-sight direction, the position of the center C_{R} of the unit region R and the position of the center C_{J} of the element joining region J formed on the joint (bump joint 5) to be joined to the semiconductor light-emitting element 3 corresponding to the unit region R are shifted from each other. The center C_{J} of the element joining region J indicates the geometric center of the element joining region J, similarly to the center C_{R} of the unit region R. In the example in FIG. 1, the element joining region J has a substantially circular shape, and the center C_{J} of the element joining region J is the center of the circle. Note that the center C_{K} of the substrate joining region K indicates the geometric center of the substrate joining region K, similarly to the center C_{R} of the unit region R.

Therefore, as shown in FIG. 1 and the like, the fact that the position of the center C_{R} of the unit region R and the position of the center C_{J} of the element joining region J are shifted from each other indicates that the position of the geometric center of the element joining region J is shifted from the geometric center of the unit region R.

In the display device 1, as shown in FIG. 1, because the center C_{J} of the element joining region J is arranged at a position shifted from the center C_{R} of the unit region R, scattered light L2 can be effectively suppressed from entering the adjacent subpixel, the scattered light L2 being generated when the leakage light L1 traveling downward from the pass-through region Q formed in the non-forming part 13 in the semiconductor light-emitting element 3 is scattered by the bump joint 5.

### (Amount of Positional Shift)

As shown in FIG. 1, a magnitude of the positional shift (an amount M of positional shift) between the center C_{J} of the element joining region J and the center C_{R} of the unit region R is preferably ¼ or more and ¾ or less of a center-to-center distance D between the unit regions R adjacent along the direction of the positional shift. The direction of the positional shift is a direction along a straight line connecting the center C_{J} of the element joining region J and the center C_{R} of the unit region R. In the example in FIG. 1, the direction of the positional shift is along the alignment direction of the semiconductor light-emitting elements 3 and is a direction along the X axis.

In the display device 1, because the amount M of positional shift described above is ¼ or more and ¾ or less of the center-to-center distance D between the unit regions R adjacent along the direction of the positional shift, the scattered light L2 can be more effectively suppressed from entering the area of the adjacent subpixel. In particular, in a case where the light-emission colors of the adjacent subpixels are different along the direction of the positional shift, the color of the adjacent subpixel and the color of the scattered light L2 can be avoided from being mixed. From the viewpoint of enhancing such an effect, the amount M of positional shift is more preferably about ½ of the center-to-center distance D between the unit regions R adjacent along the direction of positional shift, and still more preferably ½ of the center-to-center distance D between the unit regions R adjacent along the direction of positional shift.

### (Size of Element Joining Region)

As shown in FIG. 1, in a case where the adjacent unit regions R are separated from each other and the direction in which the display panel and the drive substrate face each other is the line-of-sight direction, the element joining region J is preferably located in a region W between the adjacent unit regions R from the viewpoint of suppressing generation of the scattered light L2.

### (Shape of Side Surface Part of Bump Joint)

The bump joint 5 has a shape having a portion extending in the outer direction (XY plane direction) with respect to the element joining region J, and in the example in FIG. 1, a side surface part 19 of the bump joint 5 forms a curved surface curved in a protruding shape. Note that the entire side surface part 19 of the bump joint 5 may be curved in a protruding shape, or a part thereof may be curved in a protruding shape. In the example in FIG. 1, the curved surface formed on the side surface part 19 is curved in a protruding shape so as to form a protruding end 20 at a position between the one end (the connection end 5A) and the other end (the connection end 5B) of the bump joint 5.

With respect to the position of the side surface part 19 of the bump joint 5, in a case where the direction in which the display panel 2 and the drive substrate 4 face each other is the line-of-sight direction, the position of the side surface part 19 of the bump joint 5 is preferably determined such that the protruding end 20 of the side surface part 19 curved in a protruding shape is arranged at a position avoiding the pass-through region Q as described above.

### (Underfill Layer)

A gap space 24 formed between the display panel 2 and the drive substrate 4 connected via the bump joint 5 is filled with an underfill material. Further, the underfill material filled in the gap space 24 constitutes an underfill layer 21. As the underfill material, a thermosetting resin or the like can be used.

### (Effects)

In the display device 1 according to the first embodiment, the bump joint 5 is arranged such that the center C_{J} of the element joining region J is shifted from the center C_{R} of the unit region R. Therefore, in a case where the scattered light L2 is generated by the leakage light L1 propagating downward from the light-emitting layer 12 through the pass-through region Q formed in the non-forming part 13 being scattered by the bump joint 5, the scattered light L2 is returned to the light-emitting layer 12 side of the semiconductor light-emitting element 3 from which the leakage light L1 is propagated, and the scattered light L2 is less likely to be directed toward the semiconductor light-emitting element 3 of the adjacent subpixel. Therefore, in the display device 1, the scattered light can be suppressed from entering the area of the adjacent subpixel.

In addition, in the display device 1 according to the first embodiment, because the scattered light L2 is returned to the light-emitting layer 12 side of the semiconductor light-emitting element 3 from which the leakage light L1 is propagated, the light utilization efficiency is improved, and a display device excellent in luminance can be obtained.

### 1-2. Modified Examples

### Modified Example 1

### (Position of Side Surface Part of Bump Joint)

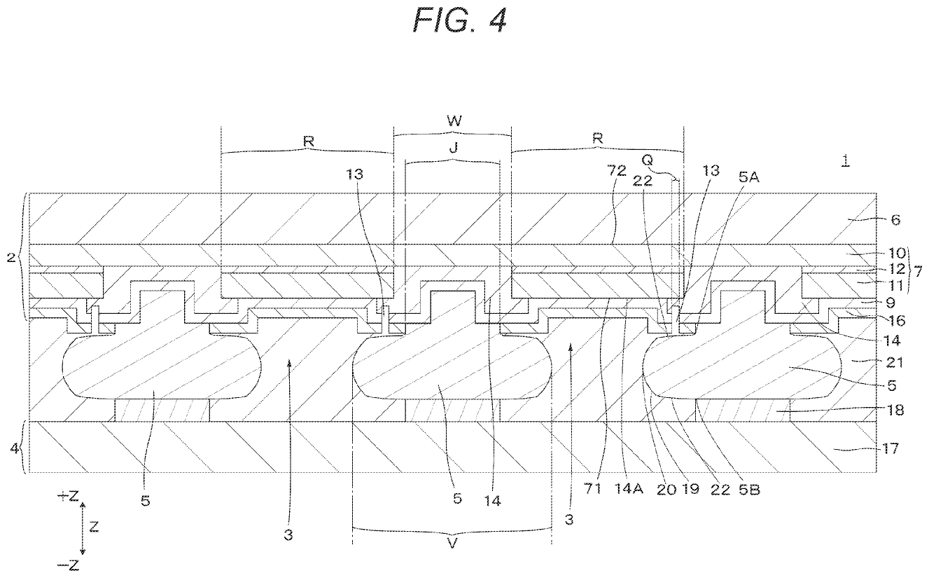

With respect to the position of the side surface part 19 of the bump joint 5, as shown in FIGS. 3 and 4, in a case where the direction in which the display panel 2 and the drive substrate 4 face each other is the line-of-sight direction, not only the protruding end 20 of the side surface part 19 curved in a protruding shape, but also the entire side surface part 19 may be arranged avoiding the pass-through region Q as already described, before the position of the side surface part 19 of the bump joint 5 is determined. This can be realized by specifying the size and the position of the bump joint 5.

For example, as shown in FIG. 3, in a case where the direction in which display panel 2 and the drive substrate 4 face each other is the line-of-sight direction, a size V of the bump joint 5 may be set to a size that allows the bump joint 5 to fall within the region W between the adjacent unit regions. At this time, in the bump joint 5, the element joining region J is also formed so as to be positioned in the region W between the adjacent unit regions. In this case, in a case where the direction in which the display panel 2 and the drive substrate 4 face each other is the line-of-sight direction, the entire bump joint 5 can be positioned in the region W between the adjacent unit regions, and the side surface part 19 of the bump joint 5 is arranged at the position avoiding the pass-through region Q. Therefore, the leakage light L1 from the pass-through region Q can be suppressed from scattering at the side surface part 19 of the bump joint 5, and the scattered light L2 can be suppressed from entering into the adjacent subpixel.

As shown in FIG. 4, the size of the bump joint 5 may be set such that the side surface part 19 curved in a protruding shape is arranged at a position closer to the center side of the unit region R than the pass-through region Q. For example, in the example in FIG. 4, an extended surface 22 extending in a plane direction (XY plane direction) with the Z-axis direction as a normal direction is formed between the end of the bump joint 5 and the side surface part 19, that is, between the end edge of the element joining region J at the connection end 5A and the side surface part 19 along the outer peripheral surface of the bump joint 5, and the extended surface 22 is formed to be more gently inclined than the side surface part 19. In a case where the direction in which the display panel 2 and the drive substrate 4 face each other is the line-of-sight direction, the extended surface 22 faces the pass-through region Q. In this case, light propagating from the semiconductor light-emitting element 3 to the drive substrate 4 side through the pass-through region Q is easily reflected by the extended surface 22 of the bump joint 5 and returned to the original pass-through region Q as it is.

### Modified Example 2

### (Modified Example of Shift Direction of Center of Element Joining Region)

In the display device 1 shown in the example in FIG. 1, the bump joint 5 is provided at the position shifted in the X-axis direction from the center C_{R} of the unit region R, that is, the direction of the positional shift of the element joining region J is the direction along the X-axis direction. In the display device 1, the direction of the positional shift of the element joining region J is not limited to the X-axis direction, and may be, for example, the Y-axis direction, or may be a direction (an arrow P direction in FIG. 5) obliquely crossing the X axis in a plane stretched by the X axis and the X axis as shown in FIG. 5. Furthermore, the amount M of positional shift of the center C_{J} of the element joining region J in the P direction is preferably within a range of ¼ or more and ¾ or less of the center-to-center distance D between the unit regions R adjacent in the P direction, and more preferably approximately ½ of the center-to-center distance D between the unit regions R adjacent in the P direction. These are applied similarly in modified examples 3 to 6 as described later.

### Modified Example 3

### (Modified Example of Shape of Bump Joint)

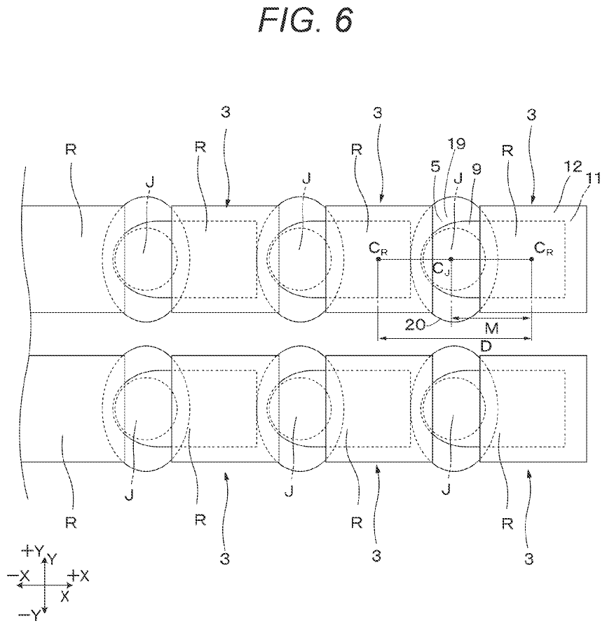

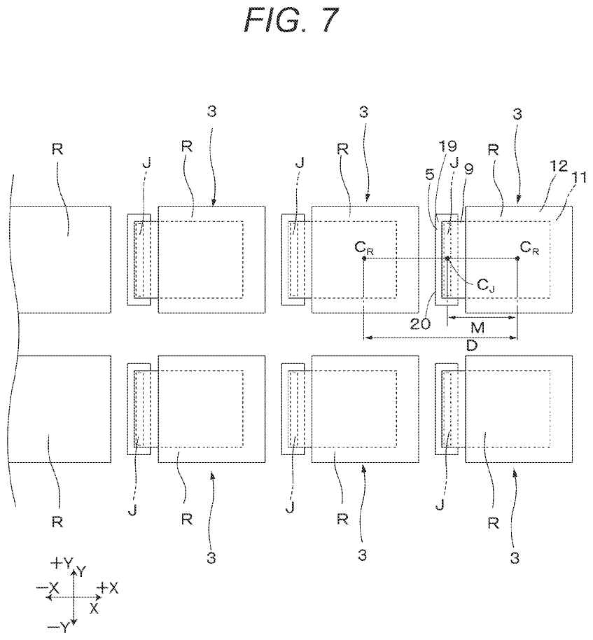

Furthermore, in the example in FIG. 1, in a case where the Z-axis direction is the line-of-sight direction, the external contour shape of the bump joint 5 is circular, but the present invention is not limited thereto. The external contour shape of the bump joint 5 may be formed in, for example, an elliptical shape as shown in FIG. 6, or may be formed in a rectangular shape as shown in FIG. 7.

Note that in the example in FIG. 6, the case is exemplified that, in a case where the Z-axis direction is the line-of-sight direction, the external contour shape of the bump joint 5 is elliptical and the element joining region J is circular. In the display device 1, the element joining region J may be elliptical.

In the example in FIG. 7, the case is exemplified that, in a case where the Z-axis direction is the line-of-sight direction, the external contour shape of the bump joint 5 is rectangular and the element joining region J is rectangular. The center C_{J} of the element joining region J in this case is an intersection position of two diagonal lines in the rectangle. Note that FIG. 7 also corresponds to the first modified example described above. That is, in the example in FIG. 7, the element joining region J is arranged in the region W between the adjacent unit regions R, and the side surface part 19 of the bump joint 5 is also located in the region W between the adjacent unit regions.

### Modified Example 4

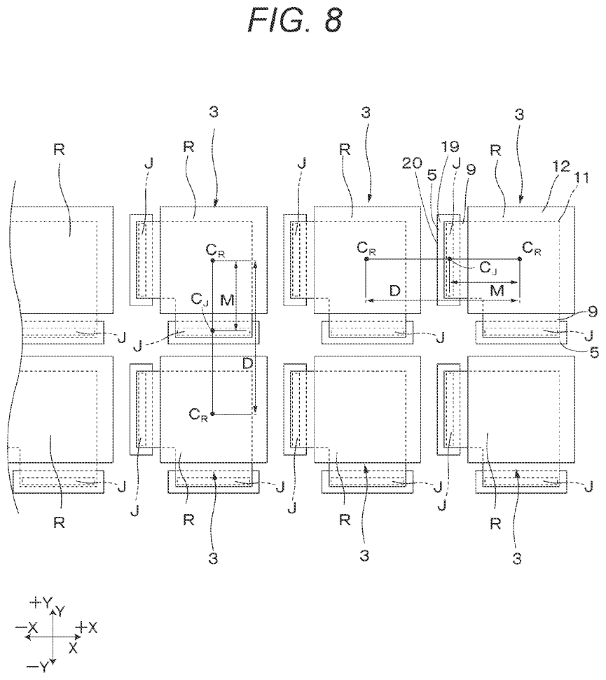

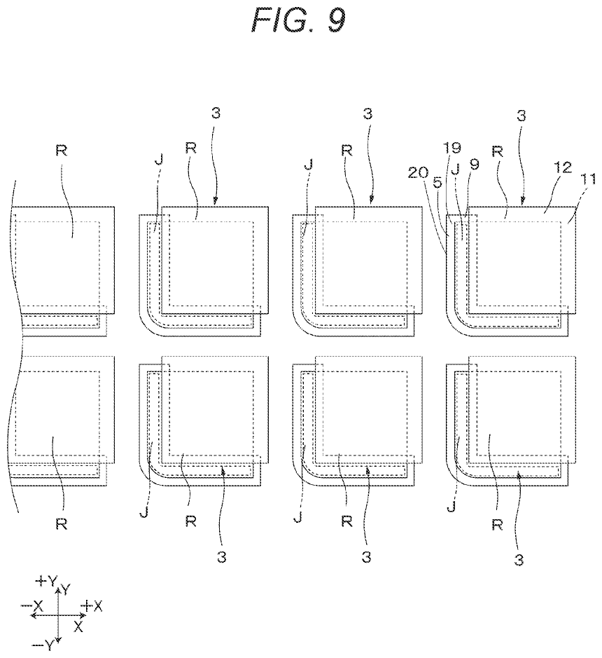

In the description of the display device 1 of the first embodiment and the third modified example, the positional shift direction of the element joining region J of the bump joint 5 is one direction. However, the present invention is not limited to this example. For example, as shown in FIG. 8, the bump joint 5 having the X-axis direction as the positional shift direction of the element joining region J and the bump joint 5 having the Y-axis direction as the positional shift direction of the element joining region J may be connected to the second electrode 9 of one semiconductor light-emitting element 3. In the example in FIG. 9, the case is exemplified that, for both of the bump joint 5 having the X-axis direction as the positional shift direction and the bump joint 5 having the Y-axis direction as the positional shift direction, the external contour shape of the bump joint 5 is rectangular in a case where the Z-axis direction is the line-of-sight direction, and the element joining region J is rectangular.

### Modified Example 5

In the example of the display device 1 shown in the fourth modified example described above, the element joining region J of the bump joint 5 having the X-axis direction as the positional shift direction and the element joining region J of the bump joint 5 having the Y-axis direction as the positional shift direction are provided in a separated state. However, as shown in FIG. 9, the element joining region J of the bump joint 5 having the X-axis direction as the positional shift direction and the element joining region J of the bump joint 5 with the Y-axis direction as the positional shift direction may be connected to each other. This can be realized, for example, by having a shape in which an end (−Y direction end) in the longitudinal direction of the bump joint 5 having the X-axis direction as the shift direction and an end (−X direction end) in the longitudinal direction of the bump joint 5 with the Y-axis direction as the shift direction in the example in FIG. 8 are connected to each other. In the display device 1 shown in FIG. 9, a state in which the bump joint 5 is formed in an L shape as a whole and is arranged at a peripheral position of the semiconductor light-emitting element 3 is established. Note that the bump joint 5 is not limited to the L-shape, and may be formed in a U-shape or an annular shape and be in a state of being arranged at a peripheral position of the semiconductor light-emitting element.

As described in the second to fifth modified examples described above, in the display device 1, in a case where the Z-axis direction is set as the line-of-sight direction, the shapes of the bump joint 5 and the element joining region J may have a shape selected from the group consisting of a circular shape, an elliptical shape, a quadrangular shape, and an L shape.

### Modified Example 6

### (Honeycomb-Shaped Arrangement)

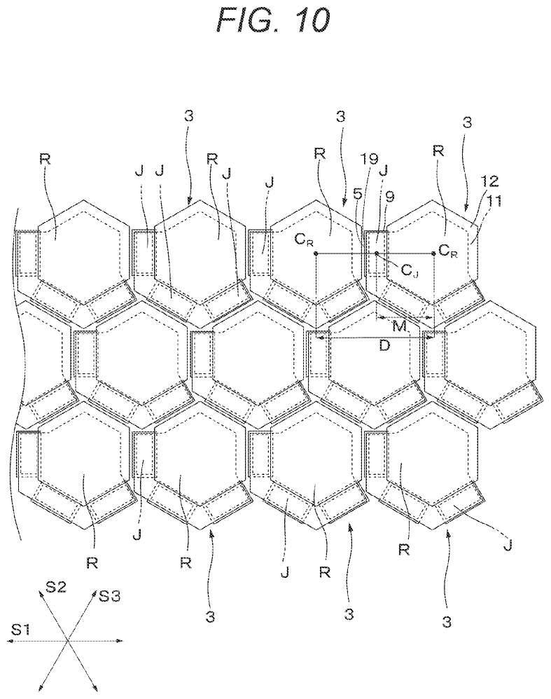

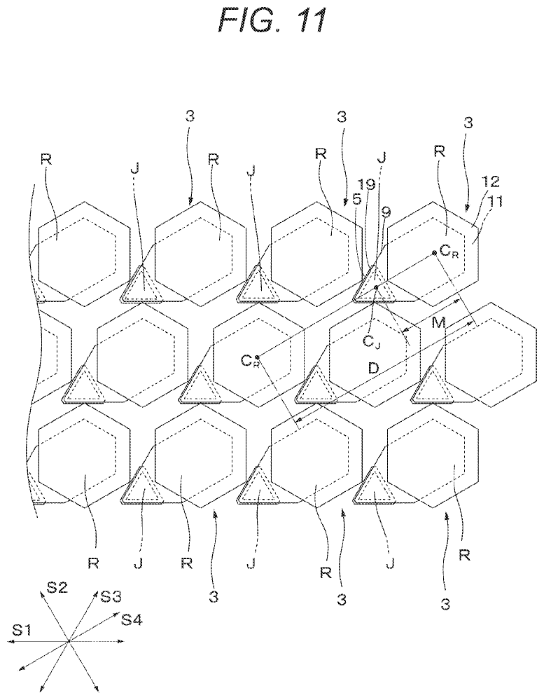

In the example of the display device 1 shown in FIG. 1, the individual unit regions R are formed in a rectangular shape, and the unit regions R are arranged in a matrix shape, but the shape and the arrangement of the unit regions R are not limited thereto, and as shown in FIGS. 10 and 11, the individual unit regions R may be formed in a hexagonal shape, and these unit regions R may be arranged in a honeycomb shape.

In the example of the display device 1 shown in FIG. 10, an S1 axis, an S2 axis, and an S3 axis are defined in the in-plane direction of the unit region R. The S1 axis, the S2 axis, and the S3 axis are arranged at positions rotated clockwise with respect to the center C_{R} position of the unit region R. The S2 axis is an axis rotated by 60° with respect to the S1 axis. The S3 axis is an axis rotated by 60° with respect to the S2 axis. Furthermore, the S1 axis, the S2 axis, and the S3 axis are set in directions in which the sides constituting the adjacent unit regions R face each other.

In the display device 1 in FIG. 10, there is formed a plurality of the centers C_{J} of the element joining regions J of the bump joint 5 as an example of the joint, and the centers C_{J} of the element joining regions J are formed at positions shifted from the center C_{R} of the unit region R in the axial directions of the S1 axis, the S2 axis, and the S3 axis, respectively.

In a case where the unit regions R are arranged in a honeycomb shape, the element joining region J may be formed such that a direction in which the center C_{J} positional shift direction of the element joining region J of the bump joint 5 obliquely intersects with any of the axial directions of the S1 axis, the S2 axis, and the S3 axis is set as a direction of positional shift direction. For example, as shown in FIG. 11, the element joining region J of the bump joint 5 may be formed at a position between three unit regions R arranged in a delta shape. In the display device shown in FIG. 11, the center C_{J} of the element joining region J is formed at a position shifted in an S4 axis direction from the center C_{R} of the unit region R. The S4 axis is in the in-plane direction of the unit region R, passes through the apex of the unit region R, and is defined in a direction orthogonal to the S2 axis.

Even in a case where the unit regions R are arranged in a honeycomb shape, in a case where the Z-axis direction is set as the line-of-sight direction, the external contour shape of the element joining region J and the bump joint 5 is not particularly limited, but in the example in FIG. 10, the element joining region J and the bump joint 5 are formed in a rectangular shape, and in the example in FIG. 11, the element joining region J and the bump joint 5 are formed in a triangular shape.

### 1-3. Manufacturing Method of Display Device

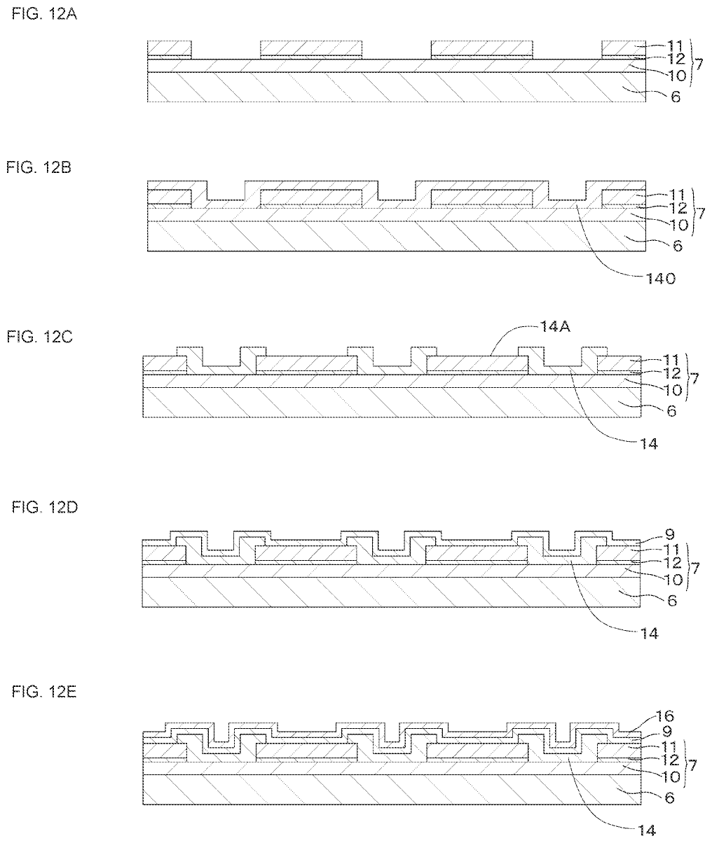

Next, in a case where the display device is the display device according to the first embodiment, a manufacturing method of the display device is exemplified as shown in FIGS. 12 to 14.

An element substrate is prepared, the first compound semiconductor layer 10, the light-emitting layer 12, and the second compound semiconductor layer 11 are patterned in this order on the first main surface of the element substrate 6 (FIG. 12A), and a first electrode is formed at a predetermined position on the first compound semiconductor layer. At this time, the laminated structure 7 is formed. The formation and lamination of the second compound semiconductor layer 11, the light-emitting layer 12, and the first compound semiconductor layer 10 can be performed using a combination of a crystal growth method, a lithography method, a dry etching method, and a wet etching method. Known techniques may be used for the crystal growth method, the lithography method, the dry etching method, and the wet etching method.

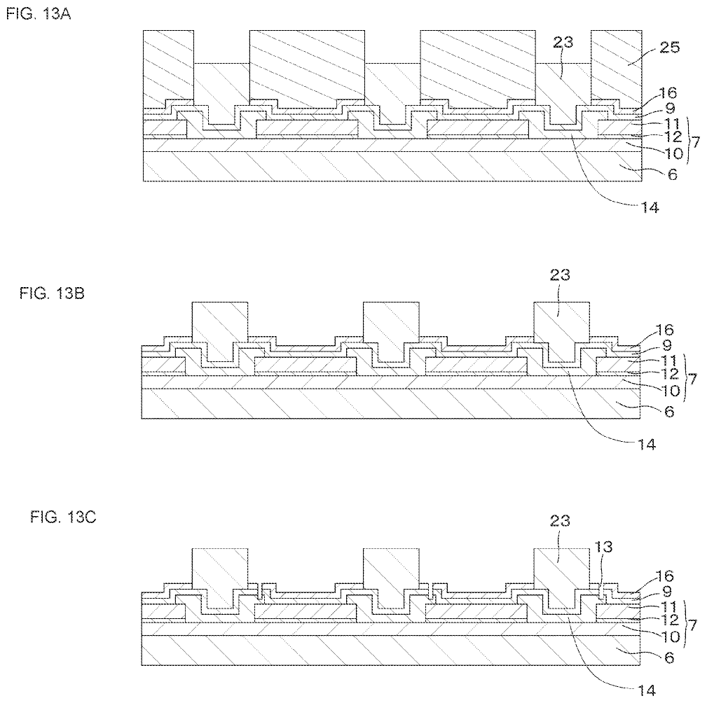

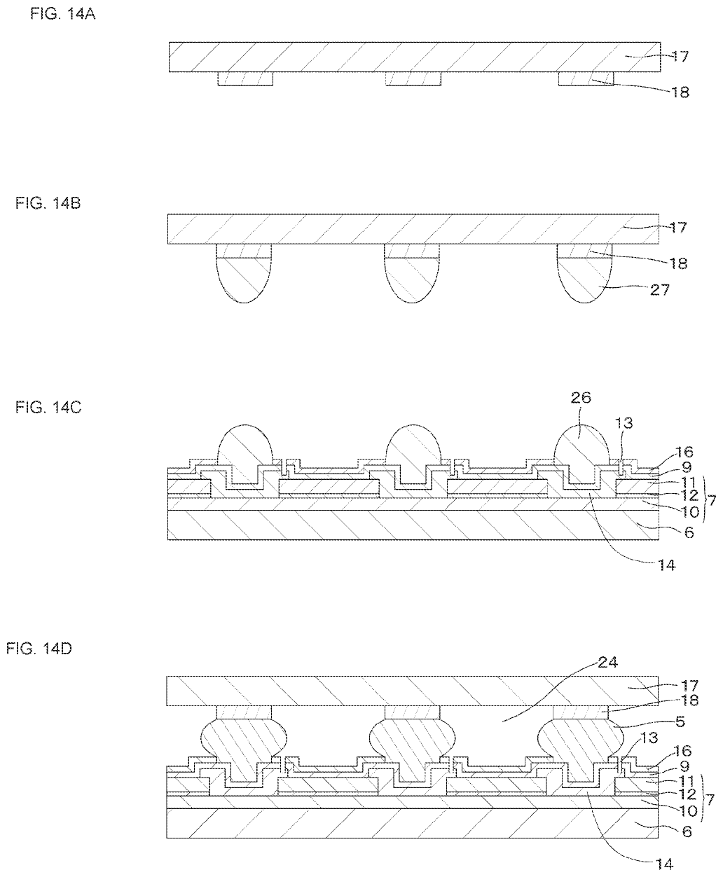

Next, as shown in FIG. 12B, an insulating film 140 is formed so as to cover the surfaces of the first compound semiconductor layer 10 and the laminated structure 7. In the insulating film 140, a portion formed in a predetermined region on the first main surface 71 of the laminated structure 7 is removed. At this time, the opening 14A is formed at the removed portion. Then, the first main surface 71 of the laminated structure 7 is exposed in the opening 14A (FIG. 12C). In addition, the remaining portion of the insulating film 140 forms the insulating layer 14. Next, the second electrode 9 and the seed layer (not illustrated) are laminated in this order so as to cover the insulating layer 14 and the first main surface 71 of the laminated structure 7 (FIG. 12D), and the inorganic film 16 is further laminated (FIG. 12E). A resist 25 is arranged on the surface of the inorganic film 16, and the inorganic film 16 is patterned using the lithography method or the like to expose the seed layer (in the drawing, the second electrode is exposed) (inorganic film forming step). After the inorganic film forming step, plating is further performed on the exposed portion of the seed layer (plating step), and a columnar body 23 is formed on the second electrode 9 or the seed layer (FIG. 13A). The plating includes material that forms a bump such as solder. After the plating step, the resist 25 is removed (FIG. 13B). Then, patterning is performed on each of the second electrode 9 and the seed layer using the etching method or the like to form the non-forming part 13 of the second electrode 9, the seed layer, and the inorganic film 16 (FIG. 13C) (non-forming part forming step). At this time, a state in which the second electrode 9 is separated for every semiconductor light-emitting element 3 is established. That is, by establishing the state in which the adjacent semiconductor light-emitting elements 3 are separated from each other in the non-forming part forming step, a state in which the plurality of semiconductor light-emitting elements 3 is formed on the element substrate 6 is established. The element substrate 6 on which the plurality of semiconductor light-emitting elements 3 is formed is accommodated in a reflow furnace and subjected to reflow processing. As a result, the tip of the columnar body 23 is rounded, and the bumps 26 are formed on the plurality of semiconductor light-emitting elements 3 (FIG. 14C).

As the drive substrate 4 having a drive circuit, one in which the seed layers 18 and the bumps 27 are formed on the substrate 17 at positions corresponding to the bumps 26 on the element substrate 6 described above is prepared (FIG. 14A and FIG. 14B). The substrate 17 is arranged on the element substrate 6 with the surface of the substrate 17 on the side of which the bumps 27 are formed facing the bumps 26 on the element substrate 6.

The bumps 27 formed on the substrate 17 constituting the drive substrate 4 and the bumps 26 formed on the element substrate 6 are joined. At this time, the bump joint 5 is formed (FIG. 14D). At this time, a state in which the display panel 2 and the drive substrate 4 are connected by the bump joint is established. Examples of a joining method include a method in which the bump 27 on the drive substrate 4 side and the bump 27 on the semiconductor light-emitting element 3 side are brought into contact with each other in a state where the bumps 26 and 27 are melted, and a method in which the bump 27 on the drive substrate 4 side and the bump 26 on the semiconductor light-emitting element 3 side are pressure-bonded in a state where the bumps 26 and 27 are not melted. After the bump joint 5 is formed, the gap space 24 formed between the display panel 2 and the drive substrate 4 is filled with an underfill material. Then, by curing the filled underfill material, the underfill layer 21 is formed. Thus, the display device 1 is formed.

### 2. Second Embodiment

### 2-1. Configuration of Display Device

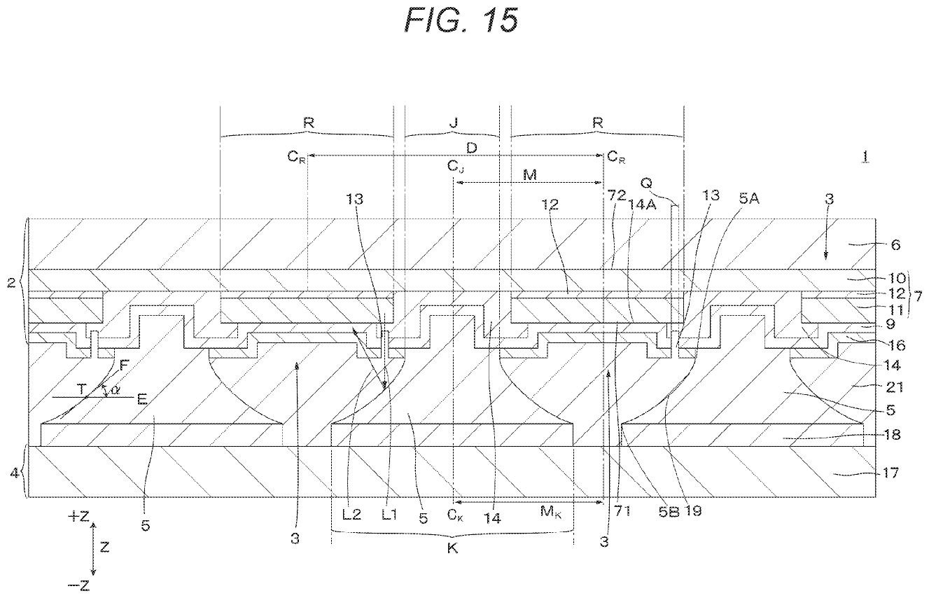

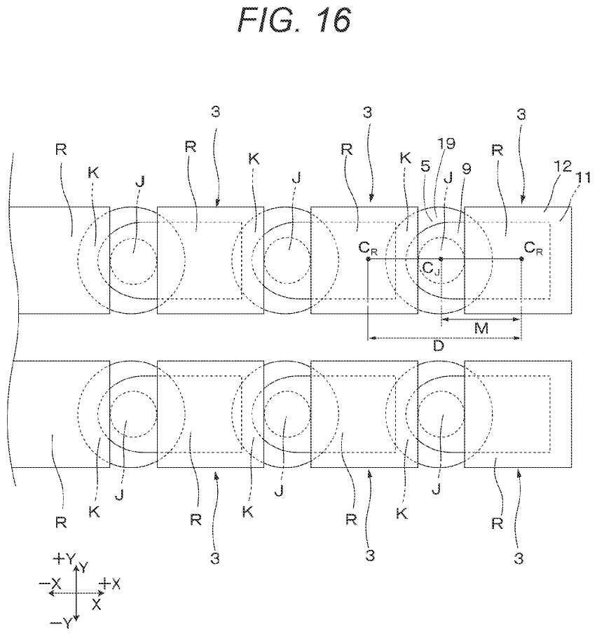

In the display device 1 according to the first embodiment, as shown in FIG. 15, a substrate joining region K formed at the other end (an other connection end 5B) may be larger than an element joining region J formed at the one end (one connection end 5A) (second embodiment). The fact that the substrate joining region K is larger than the element joining region J indicates that the element joining region J is located on the inner side of the substrate joining region K in a case where the Z-axis direction is the line-of-sight direction as shown in FIGS. 15, 16, and the like. Note that also in a display device 1 according to the second embodiment, similarly to the display device 1 according to the first embodiment, the description is continued by taking a case where the joint is a bump joint 5 as an example.

In the bump joint 5, as described later from the viewpoint of ease of forming the bump joint 5, a side surface part 19 of the bump joint 5 preferably forms a curved surface curved in a recessed or protruding shape from the one connection end 5A to the other connection end 5B along the Z-axis direction.

In a case where the bump joint 5 has a side surface part curved in a recessed shape from the one connection end 5A to the other connection end 5B, as shown in FIG. 15, the side surface part 19 forms a curved surface in which an inclination gradually becomes gentle from the +Z direction toward the −Z direction. Note that the inclination indicates the gradient of the side surface part 19 with respect to the horizontal plane (XY plane stretched by the X axis and the Y axis). In the example in FIG. 15, for example, the gradient at a position T of the side surface part 19 is indicated by an angle α formed by a contact surface F and a horizontal surface E at the position T of the side surface part 19.

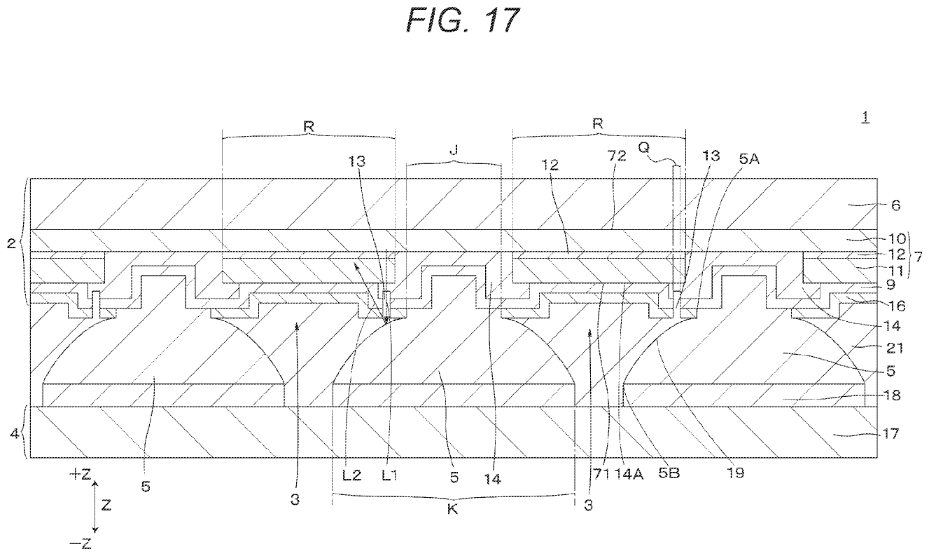

In a case where the bump joint 5 has a side surface part curved in a protruding shape from the one connection end 5A to the other connection end 5B, as shown in the example in FIG. 17, the side surface part 19 forms a curved surface in which an inclination gradually becomes steep from the +Z direction toward the −Z direction.

In the display device 1 according to the second embodiment, because the bump joint 5 has a side surface part curved in a recessed or protruding shape from the one connection end 5A to the other connection end 5B along the Z-axis direction, in a case where the Z-axis direction is the line-of-sight direction, a state in which at least a part of the curved surface of the side surface part 19 is positioned immediately below a pass-through region Q can be easily established. In particular, in the display device 1 according to the second embodiment, in a case where the shape of the side surface part 19 forms a recessed curved surface, the direction of scattered light L2 is easily directed toward the side of a light-emitting layer 12 from which leakage light L1 is generated.

### (Shape and Position of Substrate Joining Region)

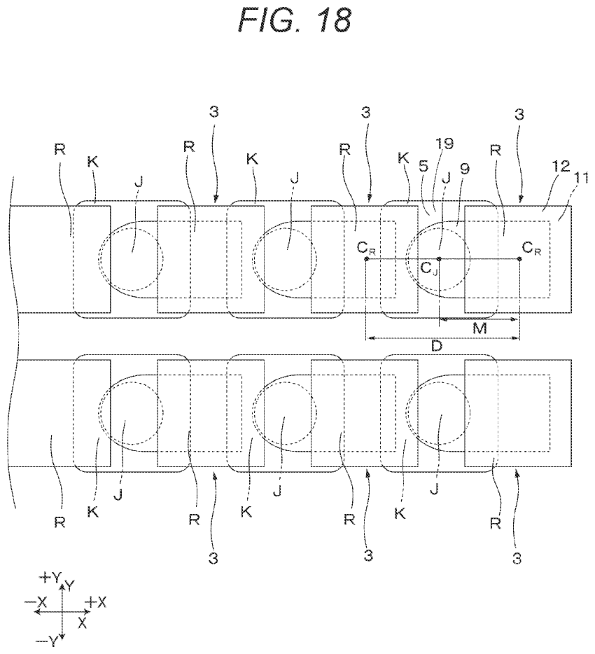

In the example in FIG. 16, the shape of the substrate joining region K is formed in a similar shape obtained by enlarging the shape of the element joining region J, and the position of the substrate joining region K is determined such that the position of a center C_{K} of the substrate joining region K substantially coincides with the position of a center C_{J} of the element joining region J in a case where the Z-axis direction is the line-of-sight direction. Therefore, in the display device 1 shown in the example in FIGS. 15 and 16, in a case where the Z-axis direction is the line-of-sight direction, the position of the center C_{R} of a unit region R and the position of the center C_{K} of the substrate joining region K formed on the bump joint 5 to be joined to a semiconductor light-emitting element 3 corresponding to the unit region R are shifted from each other in the X-axis direction similarly to the case of the center C_{J} of the element joining region J. As described in the first embodiment, the center C_{K} of the substrate joining region K indicates the geometric center of the substrate joining region K, similarly to the center C_{R} of the unit region R. In the example in FIG. 16, the substrate joining region K has a substantially circular shape, and the center C_{K} of the substrate joining region K is the center of the circle. In addition, an amount MK of positional shift of the center C_{K} of the substrate joining region K is preferably similar to the amount M of positional shift of the center C_{J} of the element joining region J described in the first embodiment. Note that, in the example in FIG. 16, in a case where the direction in which a display panel 2 and a drive substrate 4 face each other is the line-of-sight direction, the outer peripheral contour shape of the bump joint 5 coincides with the substrate joining region K. These are applied similarly to the examples in FIGS. 18 to 23.

### (Effects)

In the display device 1 according to the second embodiment, the center C_{J} of the element joining region J is shifted from the center C_{R} of the unit region R, and the size of the substrate joining region K is larger than the size of the element joining region J. Therefore, a state in which at least a part of the curved surface of the side surface part 19 is arranged immediately below the pass-through region Q can be easily established. In this case, regarding the scattered light L2 generated by the leakage light L1 propagating downward (in −Z direction) from the light-emitting layer 12 through the pass-through region Q and being scattered by the side surface part 19 of the bump joint 5, the scattered light L2 can be easily returned to the light-emitting layer 12 side through the pass-through region Q from which the leakage light L1 has passed and is less likely to be directed toward the direction of the semiconductor light-emitting element 3 side of the adjacent subpixel. Therefore, in the display device 1, the scattered light L2 can be suppressed from entering the area of the adjacent subpixel.

### 2-2. Modified Examples

### Modified Example 1

### (Modified Example of Shape of Substrate Joining Region)

In the example of the display device 1 in FIG. 16, the case where the shape of the substrate joining region K is similar to the shape of the element joining region J has been described, but the display device 1 according to the second embodiment is not limited thereto, and as shown in FIG. 18, the shape of the substrate joining region K and the shape of the element joining region J may have non-similar shapes and be different from each other. For example, in a case where the element joining region J has a circular shape, the substrate joining region K may have a non-circular shape such as an elliptical shape or a rectangular shape. In the example in FIG. 18, the element joining region J is formed in a circular shape, and the substrate joining region K is formed in a substantially rectangular shape (chamfered rectangular shape). Therefore, in the display device 1 as described above, the scattered light can be suppressed from entering the area of the adjacent subpixel.

### Modified Example 2

### (Modified Example of Shift Direction of Center of Substrate Joining Region)

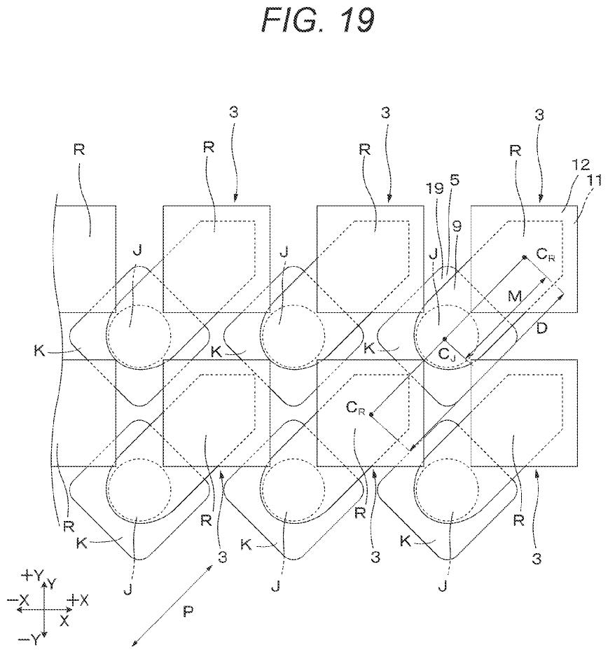

In the display device 1 shown in the examples in FIGS. 16 and 18, the element joining region J of the bump joint 5 is provided at the position shifted in the X-axis direction from the center of the unit region R, and the direction of the positional shift of the element joining region J is the direction along the X-axis direction. In the display device according to the second embodiment, the direction of the positional shift of the element joining region J is not limited to the X-axis direction. The direction of the positional shift of the element joining region J may be, for example, a direction (an arrow P direction in FIG. 19) obliquely crossing the X axis in a plane stretched by the X axis and the X axis as shown in FIG. 19, similarly to the second modified example of the first embodiment. In addition, an amount M of positional shift of the center C_{J} of the element joining region J in the P direction may be similar to the amount of positional shift of the center C_{J} of the element joining region J described the display device according to the first embodiment.

### Modified Example 3

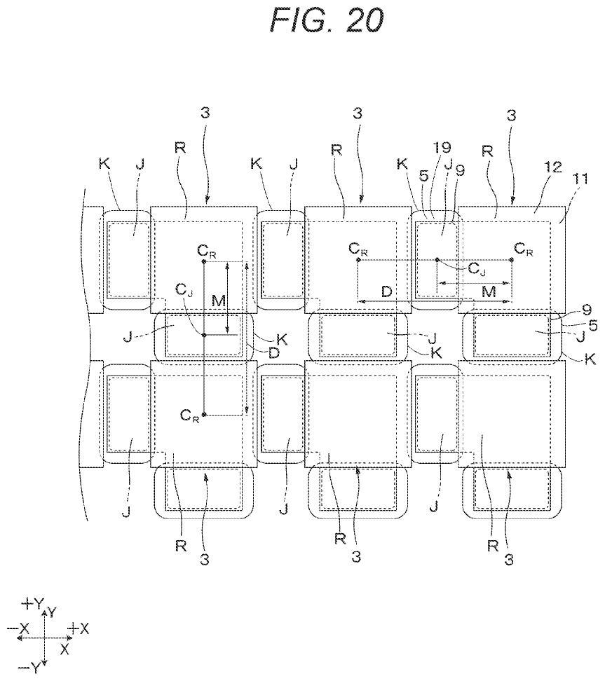

In the description of the second embodiment and the first and second modified examples, the shift direction of the element joining region J of the bump joint 5 is one direction. However, the present invention is not limited to this example, and similarly to the fourth modified example of the first embodiment, for example, as shown in FIG. 20, the bump joint 5 having the X-axis direction as the positional shift direction of the element joining region J and the bump joint 5 having the Y-axis direction as the positional shift direction of the element joining region J may be connected to a single piece of the semiconductor light-emitting element 3. In the example in FIG. 20, for both of the bump joint 5 having the X-axis direction as the positional shift direction of the element joining region J and the bump joint 5 having the Y-axis direction as the positional shift direction of the element joining region J, the case where the element joining region J and the substrate joining region K are rectangular and the substrate joining region K is larger than the element joining region J is exemplified.

### Modified Example 4

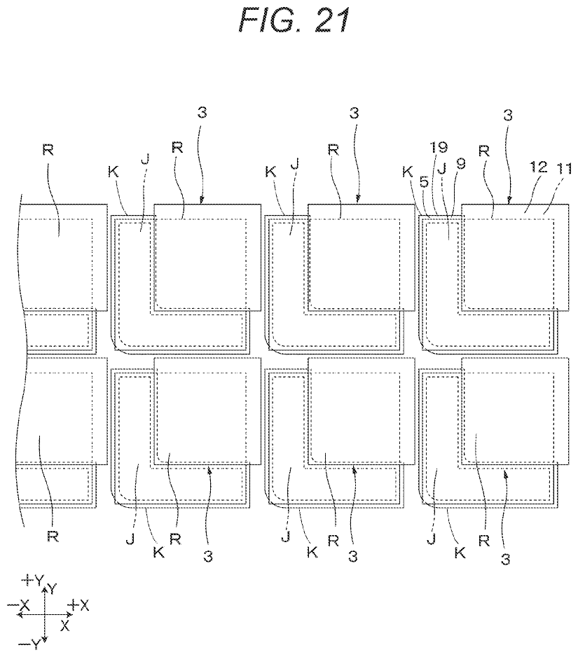

In the example of the display device 1 shown in the third modified example of the second embodiment, the bump joint 5 having the X-axis direction as the positional shift direction and the bump joint 5 having the Y-axis direction as the positional shift direction are provided in a separated state. However, similarly to the fifth modified example of the first embodiment, the element joining region J of the bump joint 5 having the X-axis direction as the positional shift direction and the element joining region J of the bump joint 5 having the Y-axis direction as the positional shift direction may be connected to each other. This can be realized, for example, by connecting an end (end on the −Y direction-side) in the longitudinal direction (Y direction) of the bump joint 5 having the X-axis direction as the shift direction and an end (end on the −X direction side) in the longitudinal direction (X direction) of the bump joint 5 having the Y-axis direction as the shift direction, which are shown in FIG. 20, are connected to each other. With this arrangement, as shown in FIG. 21, a state in which the element joining region J of the bump joint 5 having the X-axis direction as the positional shift direction and the element joining region J of the bump joint 5 having the Y-axis direction as the positional deviation direction are connected to each other can be easily established. Note that in the example shown in FIG. 21, a state shown in FIG. 20 in which the substrate joining region K of the bump joint 5 having the X-axis direction as the positional shift direction and the substrate joining region K of the bump joint 5 having the Y-axis direction as the positional deviation direction are connected to each other is also established.

In the display device 1, in the case of the example in FIG. 21, a state in which the bump joint 5 is formed in an L shape as a whole and is arranged at a peripheral position (between the adjacent unit regions R) of the semiconductor light-emitting element 3 is established. In the bump joint 5 in this example, both of the element joining region J and the substrate joining region K are formed in an L shape as a whole, and the substrate joining region K is larger than the element joining region J. Note that the bump joint 5 is not limited to the L-shape, and may be formed in a U-shape or an annular shape and be in a state of being arranged at a peripheral position of the semiconductor light-emitting element.

As described in the first to fourth modified examples described above, in the display device 1, in a case where the Z-axis direction is the line-of-sight direction, the shape of the substrate joining region K may have a shape selected from the group consisting of a circular shape, an elliptical shape, a quadrangular shape, and an L shape.

### Modified Example 5

### (Honeycomb-Shaped Arrangement)

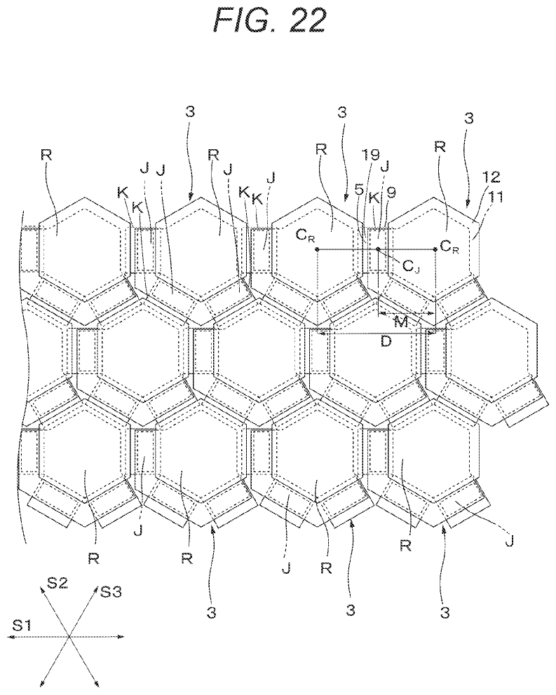

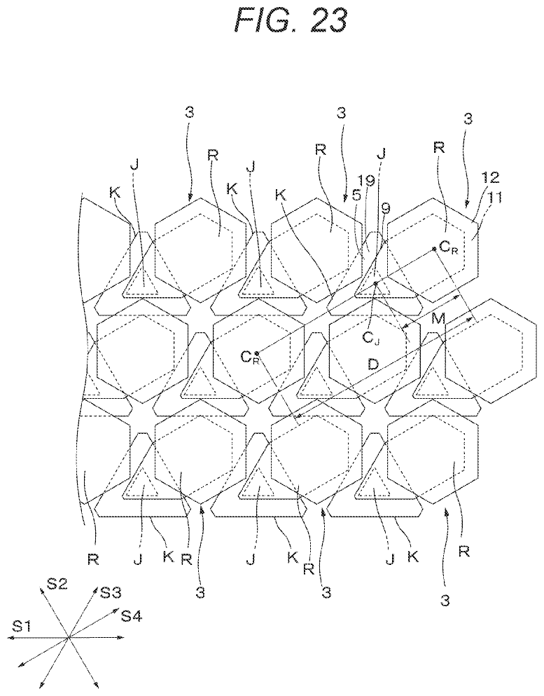

Also in the display device 1 according to the second embodiment, similarly to the sixth modified example of the first embodiment, as shown in FIGS. 22 and 23, individual unit regions R may be formed in a hexagonal shape, and these unit regions R may be arranged in a honeycomb shape. In any of the examples in FIGS. 22 and 23, the substrate joining region K is larger than the element joining region J. In the example in FIG. 22, both the element joining region J and the substrate joining region K are formed in a rectangular shape. In the example in FIG. 23, the element joining region J is formed in a triangular shape, and the substrate joining region K is formed in a shape having corners of a triangle cut off.

Note that in the display device in FIG. 22, the centers C_{J} of the element joining regions J of the bump joint 5 as an example of the joint are formed at positions shifted from the center of the unit region R in the axial directions of an S1 axis, an S2 axis, and an S3 axis, respectively. Furthermore, the S1 axis, the S2 axis, and the S3 axis are defined similarly to those shown in the sixth modified example of the first embodiment, and are in a state defined in a direction in which sides constituting the adjacent unit regions R face each other.

In the display device shown in FIG. 23, the center C_{J} of the element joining region J of the bump joint 5 is formed at a position shifted in an S4 axis direction from the center C_{R} of the unit region R. The S4 axis is defined similarly to that shown in the sixth modified example of the first embodiment.

### 3. Manufacturing Method of Display Device

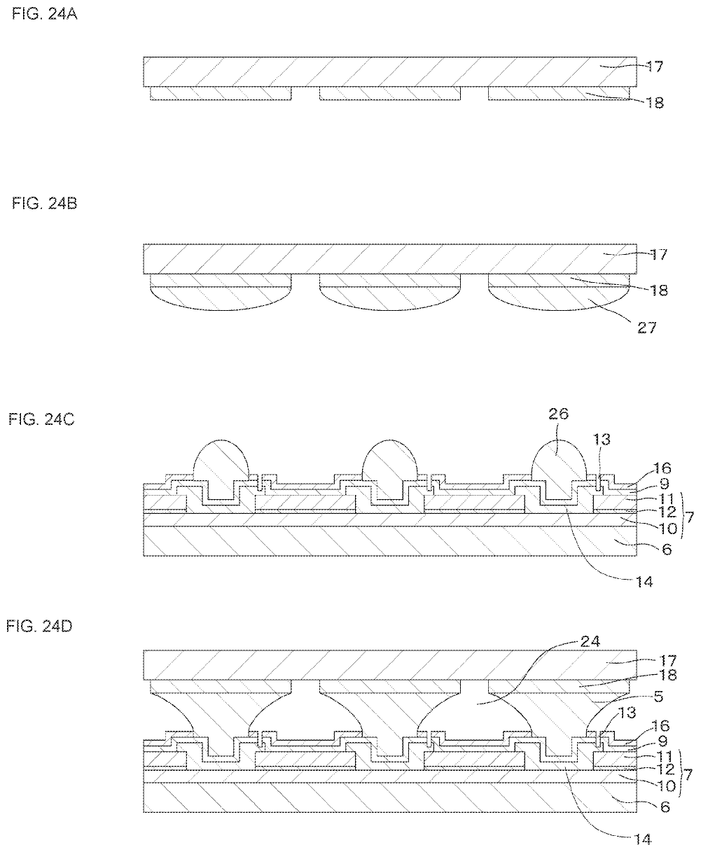

In a case where the display device is the display device 1 according to the second embodiment, a manufacturing method of the display device 1 is exemplified as shown in FIG. 24.

Steps similar to those described in the manufacturing method of the display device according to the first embodiment are performed to establish a state in which a plurality of the semiconductor light-emitting elements 3 is formed on an element substrate 6. The element substrate 6 is placed in a reflow furnace in a state where columnar bodies 23 are formed on the element substrate 6 on which the plurality of semiconductor light-emitting elements 3 is formed. Therefore, bumps 26 are formed on the element substrate 6 having the plurality of semiconductor light-emitting elements 3 (FIG. 24C).

As the drive substrate 4 having a drive circuit, one in which seed layers 18 and bumps 27 are formed on a substrate 17 at positions corresponding to the bumps 26 on the element substrate 6 is prepared (drive substrate preparation step). This drive substrate preparation step is performed in a similar manner to the manufacturing method of the display device according to the first embodiment except that the size of the bump 27 on the drive substrate 4 side (substrate 17 side) is formed larger than the size of the bump 26 on the element substrate 6 side (FIG. 24A and FIG. 24B). Then, the bumps 26 and 27 are arranged such that the surface on the substrate 17 side on which the bump 27 is formed faces the surface on the element substrate 6 side on which the bump 26 is formed.

Next, the bump 27 on the substrate 17 side is joined to the bump 26 on the element substrate 6 side. At this time, the bump joint 5 is formed (FIG. 24D). Regarding the joining method of the bumps 26 and 27, a method of bringing the bump 27 on the substrate 17 side and the bump 26 on the element substrate 6 side into contact with each other in a state where the bumps 26 and 27 are melted is suitably employed. At this time, a desired protruding curved surface or a desired recessed curved surface is formed on a side surface part 19 of the bump joint 5 by determining various conditions such as the distance between the substrate 17 and the element substrate 6 and the thermal reflow properties of the material constituting the bump. At this time, a state in which the display panel 2 and the drive substrate 4 are connected by the bump joint 5 is established.

After the bump joint 5 is formed, a gap space 24 formed between the display panel 2 and the drive substrate 4 connected is filled with an underfill material. Then, by curing the filled underfill material, the underfill layer 21 is formed. Thus, the display device 1 is formed.

### 3. Third Embodiment

### 3-1. Configuration of Display Device

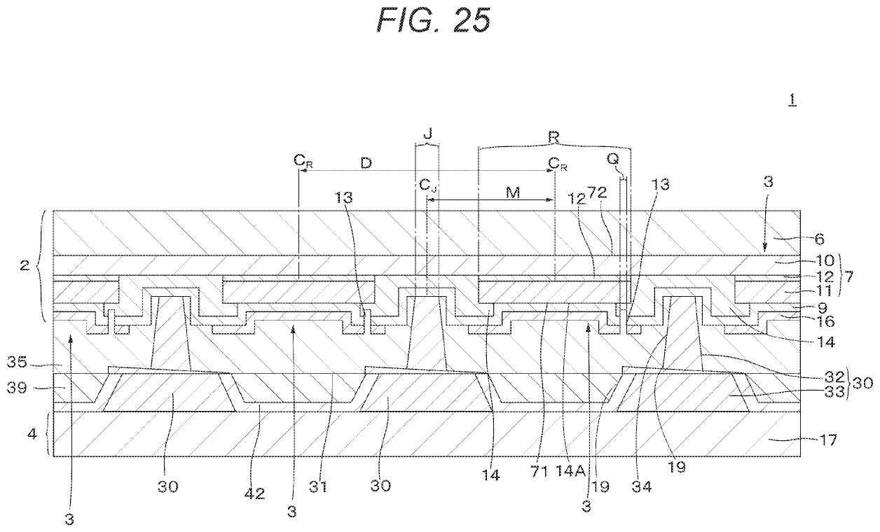

In the display device 1 according to the first embodiment, the joint is the bump joint 5, but is not limited thereto, and as shown in FIG. 25, the joint may be a Cu—Cu joint 30 (third embodiment).

In the display device according to the third embodiment, other configurations except for the Cu—Cu joint 30 may be similar to those of the display device according to the first embodiment.

### (Cu—Cu Joint 30)

The Cu—Cu joint 30 can be formed, for example, by directly joining (Cu—Cu joining) a Cu terminal 32 formed on the side of a display panel 2 and a Cu terminal 33 formed on the side of a drive substrate 4. The Cu—Cu joint 30 shown in FIG. 25 has, on a side surface part 19 thereof, an inclined surface 34 inclined upward from a position far from a semiconductor light-emitting element 3 toward the semiconductor light-emitting element 3 (+Z direction).

In a display device 1 according to the third embodiment, in the Cu—Cu joint 30, a center C_{J} of an element joining region J is shifted from a center C_{R} of a unit region R. In addition, an amount M of positional shift of the center C_{J} of the element joining region J may be similar to the amount of positional shift of the joint described the display device according to the first embodiment.

### (Effects)

Also in the display device 1 according to the third embodiment, similarly to the display device 1 according to the first embodiment, the Cu—Cu joint 30 is arranged such that the center C_{J} of the element joining region J is shifted from the center C_{R} of the unit region R. Therefore, also in the display device 1 according to the third embodiment, similarly to the display device according to the first embodiment, the scattered light is suppressed from entering the area of the adjacent subpixel.

### 3. Manufacturing Method of Display Device

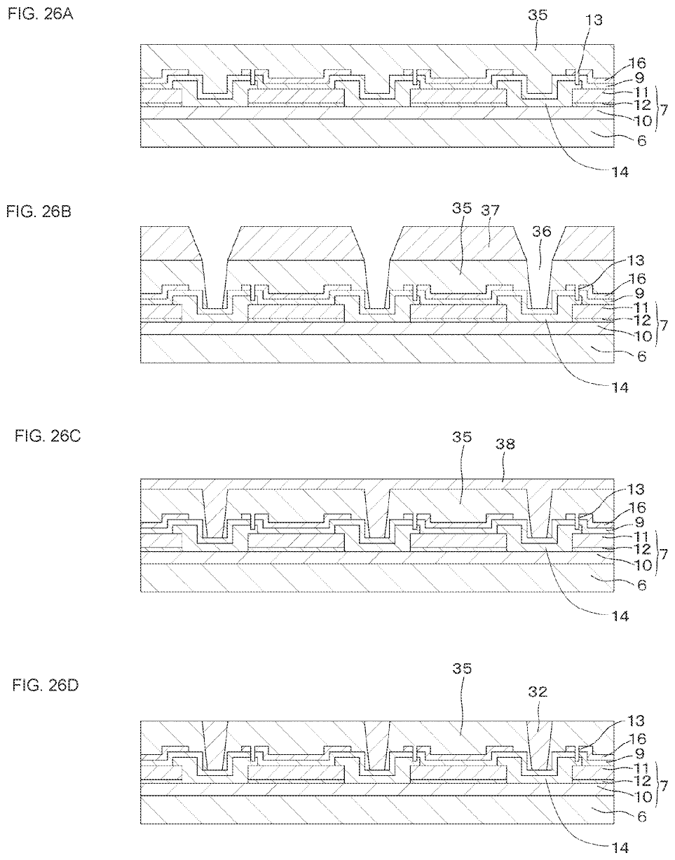

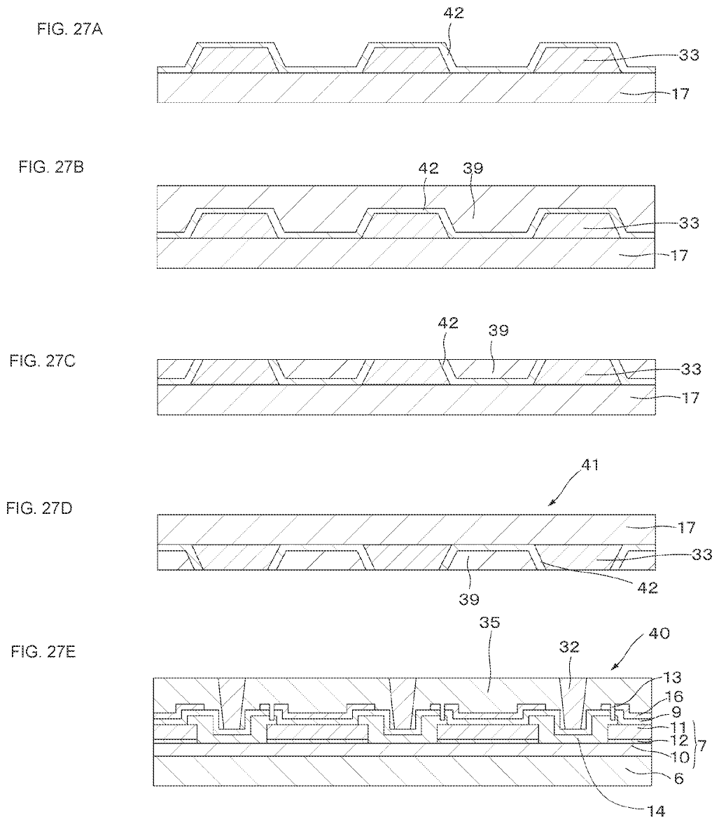

Next, in a case where the display device is the display device according to the third embodiment, a manufacturing method of the display device is exemplified as shown in FIGS. 26 and 27.

Similarly to the manufacturing method of the display device 1 according to the first embodiment, a first compound semiconductor layer 10, a light-emitting layer 12, and a second compound semiconductor layer 11 are patterned in this order on the first main surface of an element substrate 6. In addition, a first electrode 8 is formed at a predetermined position. Similarly to the manufacturing method of the display device according to the first embodiment, each step up to the inorganic film forming step is performed. Then, similarly to the manufacturing method of the display device 1 according to the first embodiment, the non-forming part forming step is performed. That is, patterning is performed on each of a second electrode 9, a seed layer 15, and an inorganic film 16 using the etching method or the like to form a non-forming part 13 of the second electrode 9, the seed layer 15, and the inorganic film 16. At this time, the second electrode 9 is separated for every semiconductor light-emitting element 3 and a plurality of the semiconductor light-emitting elements 3 is formed. Note that, unlike the display device 1 according to the first embodiment, the plating step is omitted.

An underfill material is applied to the surface of the element substrate 6 on the side of which a laminated structure 7 is formed to form an underfill layer 35 (FIG. 26A). A groove 36 is formed at a predetermined position of the underfill layer using the lithography method, the etching method, or the like (FIG. 26B). In FIG. 26B, a reference numeral 37 denotes a resist. Next, the resist 37 is removed, and the surface on the side of which the groove 36 is formed is plated with copper using a sputtering method or the like. At this time, the groove 36 is filled with copper, and a copper film 38 is further formed on the surface of the element substrate 6 on the side of which the laminated structure 7 is formed (FIG. 26C). Copper adhering to the outer side of the groove among the copper film 38 is removed by a surface planarization treatment (FIG. 26D). Therefore, a first substrate structure 40 in which the Cu terminal 32 is electrically connected to the laminated structure 7 forming the semiconductor light-emitting element 3 is formed (FIG. 27E).

The Cu terminal 33 is formed at a position corresponding to the Cu terminal 32 of the first substrate structure 40 described above on the surface of the substrate 17 constituting the drive substrate 4 including the drive circuit, and a barrier layer 42 is formed on the Cu terminal 33 (FIG. 27A). Next, an underfill layer 39 is arranged so as to cover the barrier layer 42 (FIG. 27B). Then, the surface planarization treatment is performed to expose the Cu terminal 33 (FIG. 27C). In this way, a second substrate structure 41 is prepared (FIG. 27D). Then, the Cu terminal 33 of the second substrate structure 41 is arranged to face the Cu terminal 32 of the first substrate structure 40 (FIG. 27D and FIG. 27E).

The Cu terminal 33 of the second substrate structure 41 is joined to the Cu terminal 32 of the first substrate structure 40. At this time, the underfill layer 39 of the second substrate structure 41 is also joined to the underfill layer 35 of the first substrate structure 40. In this way, the first substrate structure 40 is joined to the second substrate structure 41. With this arrangement, a state in which the display panel 2 is joined to the drive substrate 4 via the Cu—Cu joint 30 is established, and the display device 1 is formed. Note that, from the viewpoint of facilitating the joining of the underfill layers 35 and 39, the underfill layer 35 and the underfill layer 39 preferably includes the same material.

Although the examples of the embodiments of the present disclosure has been specifically described above, the present disclosure is not limited to the examples of the above-described embodiments, and various modifications based on the technical idea of the present disclosure are possible.

For example, the configurations, methods, steps, shapes, materials, numerical values, and the like mentioned in the examples of the above-described embodiments are merely examples, and different configurations, methods, steps, shapes, materials, numerical values, and the like may be used, as necessary.

In addition, the configurations, methods, steps, shapes, materials, numerical values, and the like mentioned in the examples of the above-described embodiments can be combined with each other without departing from the gist of the present disclosure.

The materials exemplified in the above-described embodiments can be used alone or in combination of two or more unless otherwise specified.

Note that the contents of the present disclosure are not to be construed as being limited by the effects exemplified in the present disclosure.

The present disclosure can also adopt the following configurations.

(1) A display device including:
a display panel including a plurality of semiconductor light-emitting elements, each of the plurality of semiconductor light-emitting elements including a light-emitting layer;
a drive substrate having a drive circuit and facing the display panel; and
a plurality of joints, each of the plurality of joints electrically connecting each of a plurality of the semiconductor light-emitting elements to the drive substrate,
in which, in a case where a direction in which the display panel and the drive substrate face each other is a line-of-sight direction, the semiconductor light-emitting element has a light-emitting region whose position at a center is shifted from a position of a center of the joint to be joined to the semiconductor light-emitting element.

(2) The display device according to (1) described above, in which the center of the joint and the center of the light-emitting region are shifted from each other with a positional shift having a magnitude of ¼ or more and ¾ or less of a center-to-center distance between the light-emitting regions adjacent to each other along a direction of the positional shift.

(3) The display device according to (1) described above, in which the center of the joint and the center of the light-emitting region are shifted from each other with a positional shift having a magnitude of about ½ of a center-to-center distance between the light-emitting regions adjacent to each other along a direction of the positional shift.

(4) The display device according to any one of (1) to (3) described above, in which,
in a case where the direction in which the display panel and the drive substrate face each other is the line-of-sight direction, a plurality of the semiconductor light-emitting elements is two-dimensionally arranged, and the center of the joint and the center of the light-emitting region are positionally shifted from each other in a direction that extends along an arrangement direction of the semiconductor light-emitting elements.

(5) The display device according to any one of (1) to (4) described above, in which
the light-emitting regions adjacent to each other are separated from each other, and
in a case where the direction in which the display panel and the drive substrate face each other is the line-of-sight direction, the joint is located in a region between the light-emitting regions adjacent to each other.

(6) The display device according to any one of (1) to (5) described above, in which
the light-emitting region has, in a part of the light-emitting region, a pass-through region through which light propagates toward the drive substrate,
the joint has a side surface part curved in a protruding shape, and is formed with an extended surface that is more gently curved than the side surface part between an end of the joint and the side surface part, and
in a case where the direction in which the display panel and the drive substrate face each other is the line-of-sight direction, the extended surface faces the pass-through region.

(7) The display device according to any one of (1) to (6) described above, in which the joint includes a bump joint.

(8) The display device according to (7) described above, in which the bump joint has a side surface part curved in a protruding shape.

(9) The display device according to any one of (1) to (8) described above, in which,
the joint has an element joining region formed at a one end along a direction in which the display panel and the drive substrate face each other, and has a substrate joining region to be joined to the drive substrate formed at an other end, and
the substrate joining region formed at the other end is larger than the element joining region formed at the one end.

(10) The display device according to (9) and dependent on any one of (1) to (7) described above, in which the joint includes a side surface part curved in a recessed or protruding shape from the one end to the other end.

(11) The display device according to (9) or (10) described above, in which, in a case where the direction in which the display panel and the drive substrate face each other is the line-of-sight direction, the substrate joining region has a shape selected from a group consisting of a circular shape, an elliptical shape, a quadrangular shape, and an L shape.

(12) The display device according to any one of (1) to (11) described above, in which the joint includes a material having reflow properties.

(13) The display device according to any one of (1) to (6) described above, in which the joint includes a Cu—Cu joint.

(14) The display device according any one of (1) to (13) described above, in which, in a case where the direction in which the display panel and the drive substrate face each other is the line-of-sight direction, the joint has a shape selected from a group consisting of a circular shape, an elliptical shape, a quadrangular shape, and an L shape.

(15) The display device according to any one of (1) to (14) described above, in which a plurality of the light-emitting regions corresponding to a plurality of the semiconductor light-emitting elements is arranged in a matrix form or a honeycomb form.

(16) The display device according to any one of (1) to (15) described above, in which each of a plurality of the semiconductor light-emitting elements is a micro light-emitting diode (LED).

(17) The display device according to any one of (1) to (16) described above, in which the semiconductor light-emitting elements adjacent to each other have different light-emission colors from each other.

### REFERENCE SIGNS LIST

1 Display device
2 Display panel
3 Semiconductor light-emitting element
4 Drive substrate
5 Bump joint (joint)
7 Laminated structure
8 First electrode
9 Second electrode
10 First compound semiconductor layer
11 Second compound semiconductor layer
12 Light-emitting layer
13 Non-forming part
14 Insulating layer
17 Substrate
18 Seed layer
30 Cu—Cu joint (joint)

1. A display device comprising:
a display panel including a plurality of semiconductor light-emitting elements, each of the plurality of semiconductor light-emitting elements including a light-emitting layer;
a drive substrate having a drive circuit and facing the display panel; and
a plurality of joints, each of the plurality of joints electrically connecting each of a plurality of the semiconductor light-emitting elements to the drive substrate,
wherein, in a case where a direction in which the display panel and the drive substrate face each other is a line-of-sight direction, the semiconductor light-emitting element has a light-emitting region whose position at a center is shifted from a position of a center of the joint to be joined to the semiconductor light-emitting element.

2. The display device according to claim 1,
wherein the center of the joint and the center of the light-emitting region are shifted from each other with a positional shift having a magnitude of ¼ or more and ¾ or less of a center-to-center distance between the light-emitting regions adjacent to each other along a direction of the positional shift.

3. The display device according to claim 1,
wherein the center of the joint and the center of the light-emitting region are shifted from each other with a positional shift having a magnitude of about ½ of a center-to-center distance between the light-emitting regions adjacent to each other along a direction of the positional shift.

4. The display device according to claim 1, wherein,
in a case where the direction in which the display panel and the drive substrate face each other is the line-of-sight direction, a plurality of the semiconductor light-emitting elements is two-dimensionally arranged, and
the center of the joint and the center of the light-emitting region are positionally shifted from each other in a direction that extends along an arrangement direction of the semiconductor light-emitting elements.

5. The display device according to claim 1, wherein
the light-emitting regions adjacent to each other are separated from each other, and
in a case where the direction in which the display panel and the drive substrate face each other is the line-of-sight direction, the joint is located in a region between the light-emitting regions adjacent to each other.

6. The display device according to claim 1, wherein
the light-emitting region has, in a part of the light-emitting region, a pass-through region through which light propagates toward the drive substrate,
the joint has a side surface part curved in a protruding shape, and is formed with an extended surface that is more gently curved than the side surface part between an end of the joint and the side surface part, and
in a case where the direction in which the display panel and the drive substrate face each other is the line-of-sight direction, the extended surface faces the pass-through region.

7. The display device according to claim 1,
wherein the joint includes a bump joint.

8. The display device according to claim 7,
wherein the bump joint has a side surface part curved in a protruding shape.

9. The display device according to claim 1, wherein
the joint has an element joining region formed at a one end along a direction in which the display panel and the drive substrate face each other, and has a substrate joining region to be joined to the drive substrate formed at an other end, and
the substrate joining region formed at the other end is larger than the element joining region formed at the one end.

10. The display device according to claim 9,
wherein the joint includes a side surface part curved in a recessed or protruding shape from the one end to the other end.

11. The display device according to claim 9,
wherein, in a case where the direction in which the display panel and the drive substrate face each other is the line-of-sight direction, the substrate joining region has a shape selected from a group consisting of a circular shape, an elliptical shape, a quadrangular shape, and an L shape.

12. The display device according to claim 1,
wherein the joint includes a material having reflow properties.

13. The display device according to claim 1,
wherein the joint includes a Cu—Cu joint.

14. The display device according to claim 1,
wherein, in a case where the direction in which the display panel and the drive substrate face each other is the line-of-sight direction, the joint has a shape selected from a group consisting of a circular shape, an elliptical shape, a quadrangular shape, and an L shape.

15. The display device according to claim 1,
wherein a plurality of the light-emitting regions corresponding to a plurality of the semiconductor light-emitting elements is arranged in a matrix form or a honeycomb form.

16. The display device according to claim 1,
wherein each of a plurality of the semiconductor light-emitting elements is a micro light-emitting diode (LED).

17. The display device according to claim 1,
wherein the semiconductor light-emitting elements adjacent to each other have different light-emission colors from each other.
